(19) United States
(12) Patent Application Publication
(10) Pub. No.: US 2017/0097870 A1
(43) Pub. Date: Apr. 6, 2017

(54) OPERATING METHOD OF MEMORY SYSTEM

(71) Applicants: SK hynix Inc., Gyeonggi-do (KR); Korea Advanced Institute of Science and Technology, Daejeon (KR)

(72) Inventors: Jeong-Seok HA, Daejeon (KR); Dae-Sung KIM, Daejeon (KR)

(21) Appl. No.: 15/050,012

(22) Filed: Feb. 22, 2016

(30) Foreign Application Priority Data
Oct. 1, 2015 (KR) 10-2015-0138644

(51) Int. Cl. G06F 11/10; G11C 29/52

(52) U.S. Cl. CPC G06F 11/1072; G11C 29/52

(57) ABSTRACT

A decoding method includes: a first step of receiving data; and a second step of obtaining total number of error-corrected bits of the received data during a predetermined total decoding operation.

### CROSS-REFERENCE TO RELATED APPLICATIONS

The present application claims priority of Korean Patent Application No. 10-2015-0138644, flied on Oct. 1, 2015, which is incorporated herein by reference in its entirety.

### BACKGROUND

1. Field

Exemplary embodiments of the present invention relate to memory system, and more particularly, to a memory system including a semiconductor memory device and an operating method thereof.

2. Description of the Related Art

Recently, a solid state drive (SSD) having a multi-level cell (MLC) flash memory has been introduced resulting in a substantial reduction of the cost per bit. However, compared with a single-level cell (SLC) flash memory, an MLC flash memory may generally have reduced data stability and higher error bit rate due to generally reduced noise margins for information stored in the memory cells. Therefore, error bits need to be corrected using an error correction method. Further, a channel condition of an MLC flash memory may be estimated by comparing before-error-correction data provided from the flash memory with error-corrected data, and obtaining a number of error-corrected bits based on the comparison. Well-known error correction codes include the Bose-Chaudhuri-Hocquenghem (BCH) code, the Reed-Solomon (RS) code, and the hamming code. In the case of block-wise, concatenated BCH (BC-BCH) data, it may be hard to estimate the channel condition of the memory based on the number of error-corrected bits obtained through comparison of before-error-correction data and error-corrected data, since there is a high probability of multiple error corrections to an error bit during a decoding operation. Therefore, further improvements are desirable.

### SUMMARY

Various embodiments of the present invention are directed to an operating method of a memory system for estimating a channel condition of a memory precisely.

According to an embodiment of the present invention, an operation method of memory system may include: a first step of receiving data; and a second step of obtaining a total number of error-corrected bits of the received data during a total decoding operation comprising one or more decoding operations. The second step may comprise: a third step of calculating error-corrected bits for each of the decoding operations; and a fourth step of obtaining the total number of error-corrected bits of the received data by accumulating calculated error-corrected bits for each of the decoding operations. The second step may comprise: a fifth step of obtaining locations of the error bits of the received data; a sixth step of error-correcting the error bits of the received data based on the locations of the error bits; and a seventh step of obtaining the total number of error-corrected bits of the received data based on the error-corrected bits. Each decoding operation of the total decoding operation may comprise a predetermined decoding operation to the row constituent code and a predetermined decoding operation to the column constituent code. An eighth step of determining whether the total decoding operation may be successful. When the total decoding operation may fail as a determination result of the sixth step, a seventh step of obtaining total number of error-corrected bits of the received data by repeating the fifth and eighth steps a predetermined number of times. When the total decoding operation may be successful as a determination result of the sixth step, providing a host with the total number of error-corrected bits of the received data obtained up to the total decoding operation and a success flag. Before performing a seventh step of obtaining total number of error-corrected bits of the received data by repeating the third and sixth steps a predetermined number of times, determining whether the total decoding operation corresponds to a predetermined last total decoding operation. When the total decoding operation may not correspond to the predetermined last total decoding operation, obtaining the total number of error-corrected bits of the received data by repeating the fifth and eighth steps a predetermined number of times. When the total decoding operation may correspond to the predetermined last total decoding operation, providing a host with the total number of error-corrected bits of the received data obtained through a predetermined number of repetition of the total decoding operation and a fail flag.

According to an embodiment of the present invention, A method for performing a predetermined total decoding operation to data comprising a plurality of row constituent codes and a plurality of column constituent codes, the method may comprises: a first step of performing a predetermined row constituent code decoding operation for the plurality of row constituent codes; a second step of performing a predetermined column constituent code decoding operation for the plurality of column constituent codes; a third step of determining whether the total decoding operation is successful; a fourth step of determining whether the total decoding operation corresponds to a last total decoding operation of the predetermined total decoding operation when the total decoding operation fails; and a fifth step of obtaining total number of error-corrected bits of the received data by repeating the first to fourth steps when the total decoding operation does not correspond to the last total decoding operation of the predetermined total decoding operation.

The first step may comprise: a sixth step of obtaining locations of the error bits of the row constituent codes; a seventh step of error-correcting the error bits of the row constituent codes based on the locations of the error bits of the row constituent codes; and a eighth step of obtaining a number of error-corrected bits of the row constituent codes based on the error-corrected bits of the row constituent codes.

A ninth step of repeating the row constituent code decoding operation until a last row constituent code in the plurality of row constituent codes.

The second step may comprise: a tenth step of obtaining locations of the error bits of the column constituent codes; an eleventh step of error-correcting the error bits of the column constituent codes based on the locations of the error bits of the column constituent codes; and a twelfth step of obtaining a number of error-corrected bits of the column constituent codes based on the error-corrected bits of the column constituent codes. A thirteenth step of repeating the column constituent code decoding operation until a last column constituent code in the plurality of column constituent codes. The total number of error-corrected bits of the received data may be determined based on the following: ê=Σₗ₌₀{Σᵢe_{r,i}^{(l)}1_{r,i}^{(l)}+Σᵢe_{c,j}^{(l)}1_{c,j}^{(l)}}, where ê denotes the total number of error-corrected bits of the received data, e_{r,i}^{(l)} denotes a number of error-corrected bits of i-th row constituent code obtained through the row constituent code decoding operation to i-th row constituent code during l-th total decoding operation of the predetermined total decoding operation, e_{c,j}^{(l)} denotes a number of error-corrected bits of j-th column constituent code obtained through the column constituent code decoding operation to j-th column constituent code during l-th total decoding operation of the predetermined total decoding operation, 1_{r,j}^{(l)} denotes a case that the number (e_{r,j}^{(l)}) of error-corrected bits in the i-th row constituent code obtained through the row constituent code decoding operation to i-th row constituent code during l-th total decoding operation of the predetermined total decoding operation is greater than one, and 1_{c,j}^{(l)} denotes a case that the number (e_{c,j}^{(l)}) of error-corrected bits in the j-th column constituent code obtained through the column constituent code decoding operation to j-th column constituent code during l-th total decoding operation of the predetermined total decoding operation is greater than one. The total number of error-corrected bits of the received data may be determined based on the following: ê=Σₗ₌₀{Σᵢ(e_{r,i}^{˜(l)}−e_{r,i}^{(l)}) 1_{r,i}^{(l)}+Σᵢ(e_{c,j}^{(l)}−e_{c,j}^{˜(l)}}, where ê denotes the total number of error-corrected bits of the received data, e_{r,i}^{(l)} denotes a number of error-corrected bits of i-th row constituent code obtained through the row constituent code decoding operation to i-th row constituent code during l-th total decoding operation of the predetermined total decoding operation, e_{c,j}^{(l)} denotes a number of error-corrected bits of j-th column constituent code obtained through the column constituent code decoding operation to j-th column constituent code during l-th total decoding operation of the predetermined total decoding operation, e_{r,i}^{˜(l)} denotes a backup number of error-corrected bits in the i-th row constituent code obtained through the row constituent code decoding operation to i-th row constituent code during l-th total decoding operation of the predetermined total decoding operation, e_{c,j}^{˜(l)} denotes a backup number of error-corrected bits in the j-th column constituent code obtained through the column constituent code decoding operation to j-th column constituent code during l-th total decoding operation of the predetermined total decoding operation, 1_{r,i}^{(l)} denotes a case that the number (e_{r,i}^{(l)}) of error-corrected bits in the i-th row constituent code obtained through the row constituent code decoding operation to i-th row constituent code during l-th total decoding operation of the predetermined total decoding operation is greater than one, and 1_{c,j}^{(l)} denotes a case that the number (e_{c,j}^{(l)}) of error-corrected bits in the j-th column constituent code obtained through the column constituent code decoding operation to j-th column constituent code during l-th total decoding operation of the predetermined total decoding operation is greater than one. The total number of error-corrected bits of the received data may be determined based on the following: ê=Σᵢ(e_{r,i}^{˜})+Σⱼ(e_{c,j}^{˜}), where ê denotes the total number of error-corrected bits of the received data, e_{r,i}^{˜} denotes a backup number of error-corrected bits in the i-th row constituent code, which is a number of error-corrected bits in the i-th row constituent code obtained through successfully completed row constituent code decoding operation to i-th row constituent code or a last row constituent code decoding operation of the predetermined row constituent code decoding operation to the plurality of row constituent codes and is stored in a backup buffer of the i-th row constituent code, and e_{c,j}^{˜}denotes a backup number of error-corrected bits in the j-th column constituent code, which is a number of error-corrected bits in the j-th column constituent code obtained through successfully completed column constituent code decoding operation to j-th column constituent code or a last column constituent code decoding operation of the predetermined column constituent code decoding operation to the plurality of column constituent codes and is stored in a backup buffer of the j-th the column constituent code. The total number of error-corrected bits of the received data may be determined based on the following: ê=Σ₁₌₀{(Σᵢ(e_{r,i}^{(l)}−2e_{r,i}^{˜(l)})1_{r,i}^{(l)}+Σᵢ(e_{c,j}^{(l)}−2e_{c,j}^{˜(l)})1_{c,j}^{(l)}}, where ê denotes the total number of error-corrected bits of the received data, e_{r,i}^{(l)} denotes a number of error-corrected bits of i-th row constituent code obtained through the row constituent code decoding operation to i-th row constituent code during l-th total decoding operation of the predetermined total decoding operation, e_{c,j}^{(l)} denotes a number of error-corrected bits of j-th column constituent code obtained through the column constituent code decoding operation to j-th column constituent code during l-th total decoding operation of the predetermined total decoding operation, e_{r,i}^{˜(l)} denotes a backup number of error-corrected bits in the i-th row constituent code obtained through the row constituent code decoding operation to i-th row constituent code during l-th total decoding operation of the predetermined total decoding operation, e_{c,j}^{˜(l)} denotes a backup number of error-corrected bits in the j-th column constituent code obtained through the column constituent code decoding operation to j-th column constituent code during l-th total decoding operation of the predetermined total decoding operation, 1_{r,i}^{(l)} denotes a case that the number (e_{r,i}^{(l)}) of error-corrected bits in the i-th row constituent code obtained through the row constituent code decoding operation to i-th row constituent code during l-th total decoding operation of the predetermined total decoding operation is greater than one, and 1_{c,j}^{(l)} denotes a case that the number (e_{c,j}^{(l)}) of error-corrected bits in the j-th column constituent code obtained through the column constituent code decoding operation to j-th column constituent code during l-th total decoding operation of the predetermined total decoding operation is greater than one. When the total decoding operation may be successful as a determination result of the third step, providing a host with the total number of error-corrected bits of the received data obtained up to the successful total decoding operation and a success flag without performing remaining total decoding operation among the predetermined total decoding operations. When the total decoding operation may correspond to the last total decoding operation of the predetermined total decoding operation as a determination result of the fourth step, providing a host with the total number of error-corrected bits of the received data obtained through the predetermined total decoding operation and a fail flag.

According to an embodiment of the present invention, a number of error-corrected bits may be obtained whenever decoding data comprising the error correction code during a predetermined decoding operation, and thus a total number of error-corrected bits may be obtained at the same time of completion of the predetermined decoding operation.

### BRIEF DESCRIPTION OF THE DRAWINGS

FIG. 1 is a block diagram illustrating a data processing system, according to an embodiment of the present invention.

FIG. 2 is a diagram illustrating an example of a structure of a flash memory.

FIG. 3A is a diagram illustrating an example of a block-wise concatenated BCH code in parallel.

FIG. 3B is a diagram illustrating an example of a block-wise concatenated BCH code in series.

FIG. 4 is a flowchart illustrating an operation of a flash memory system, according to an embodiment of the present invention.

FIG. 5 is a flowchart illustrating an operation of a flash memory system, according to an embodiment of the present invention.

FIG. 6 is a flowchart illustrating an operation of a flash memory system, according to an embodiment of the present invention.

FIG. 7 is a flowchart illustrating an operation of a flash memory system, according to an embodiment of the present invention.

FIGS. 8 to 15 are diagrams schematically illustrating a three-dimensional (3D) non-volatile memory device, according to an embodiment of the present invention.

FIG. 16 is a block diagram schematically illustrating an electronic device including a semiconductor memory system, according to an embodiment of the present invention.

FIG. 17 is a block diagram schematically illustrating an electronic device including a semiconductor memory system, according to an embodiment of the present invention.

FIG. 18 is a block diagram schematically illustrating an electronic device including a semiconductor memory system, according to an embodiment of the present invention.

### DETAILED DESCRIPTION

Various embodiments will be described below in more detail with reference to the accompanying drawings. The present invention may, however, be embodied in different forms and should not be construed as being limited to the embodiments set forth herein. Rather, these embodiments are provided so that this disclosure will be thorough and complete to those skilled in the art. Further, it is noted that the drawings are not necessarily to scale and in some instances, proportions may have been exaggerated to clearly illustrate certain features of the embodiments. Throughout the disclosure, reference numerals correspond directly to like parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also “over” something with an intermediate feature(s) or a layer(s) therebetween. When a first layer is referred to as being “on” a second layer or “on” a substrate, it not only refers to a case in which the first layer is formed directly on the second layer or the substrate but also a case in which a third layer exists between the first layer and the second layer or the substrate.

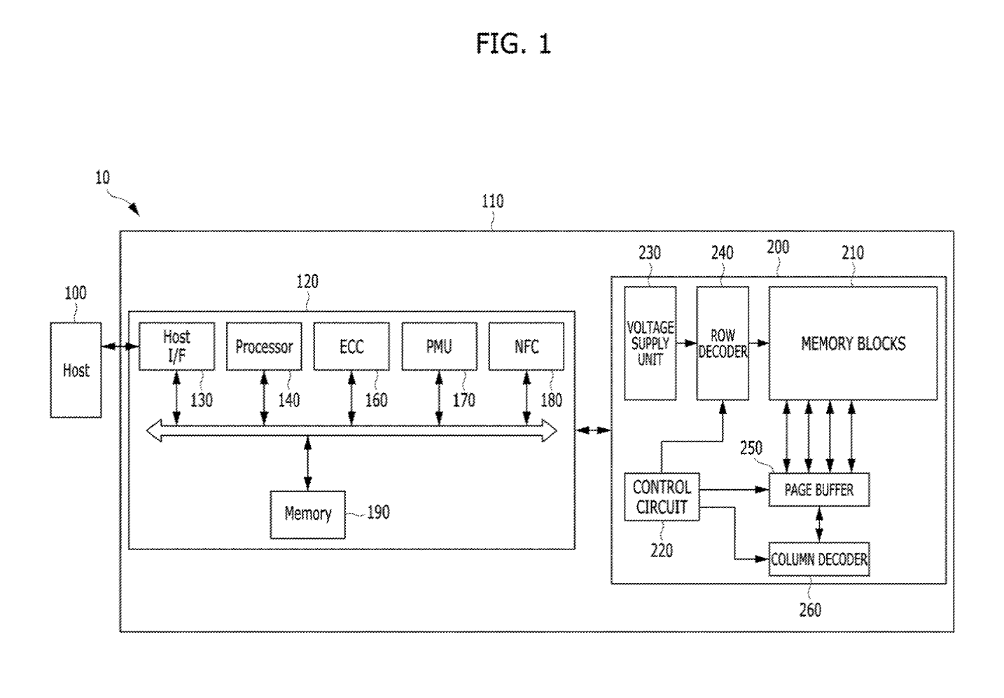

Referring now to FIG. 1, a data processing system according to an embodiment of the invention will be described. The data processing system 10 may include a host 100 and a memory system 110.

The host 100 may include, for example, a portable electronic device such as a mobile phone, an MP3 player, and a laptop computer or an electronic device such as a desktop computer, a game player, a TV, a projector and the like.

The memory system 110 may operate in response to a request of the host 100 and in particular, store data to be accessed by the host 100. For example, the memory system 110 may be used as a main memory system or an auxiliary memory system of the host 100. The memory system 110 may be implemented with any one of various kinds of storage devices, according to the protocol of a host interface to be electrically coupled with the host 100. The memory system 110 may be implemented with any one of various kinds of storage devices such as a solid-state drive (SSD), a multimedia card (MMC), an embedded MMC (eMMC), a reduced-size MMC (RS-MMC) and a micro-MMC, a secure digital (SD) card, a mini SD card, a micro SD card, a universal serial bus (USB) storage device, a universal flash storage (UFS) device, a compact flash (CF) card, a smart media (SM) card, a memory stick, and the like.

The storage device for the memory system 110 may be implemented with a volatile memory device such as a dynamic random access memory (DRAM) and a static random access memory (SRAM) or a nonvolatile memory device such as a read only memory (ROM), a mask ROM (MROM), a programmable ROM (PROM), an erasable programmable ROM (EPROM), an electrically erasable programmable ROM (EEPROM), a ferroelectric random access memory (FRAM), a phase change RAM (PRAM), a magnetoresistive RAM (MRAM), a resistive RAM (RRAM), and the like. One or more storage devices may be used.

A memory system 110 may include a memory device 200 which may store data to be accessed by the host 100, and a controller 120 which may control storage of data in the memory device 200.

The controller 120 and the memory device 200 may be integrated into a semiconductor device and configured as a memory card. For instance, the controller 120 and the memory device 200 may be integrated into a semiconductor device and configured as a solid state drive (SSD). When the memory system 110 is used as the SSD, the operation speed of the host 100 that is electrically coupled with the memory system 110 may be significantly increased.

The controller 120 and the memory device 200 may be integrated into a semiconductor device and configured as a memory card. For example, the controller 120 and the memory device 200 may be integrated into a semiconductor device and configured as a memory card such as a personal computer memory card international association (PCMCIA), a compact flash (CF) card, a smart media (SM) card (SMC), a memory stick, a multimedia card (MMC), a reduced-size (RS)MMC, a micro-MMC, a secure digital (SD) card, a mini-SD SD card, a micro-SD card, a secure digital high capacity (SDHC), and a universal flash storage (UFS) device.

In an embodiment, the memory system 110 may be or configure a computer, an ultra-mobile PC (UMPC), a workstation, a net-book, a personal digital assistant (PDA), a portable computer, a web tablet, a tablet computer, a wireless phone, a mobile phone, a smart phone, an e-book, a portable multimedia player (PMP), a portable game player, a navigation device, a black box, a digital camera, a digital multimedia broadcasting (DMB) player, a three-dimensional (3D) television, a smart television, a digital audio recorder, a digital audio player, a digital picture recorder, a digital picture player, a digital video recorder, a digital video player, a storage configuring a data center, a device capable of transmitting and receiving information under a wireless environment, one of various electronic devices configuring a home network, one of various electronic devices configuring a computer network, one of various electronic devices configuring a telematics network, an RFID device, one of various component elements configuring a computing system, and the like.

The memory device 200 of the memory system 110 may retain stored data even when power supply is interrupted. In particular, the memory device 200 may store the data provided from the host 100 through a write operation, and provide stored data to the host 100 through a read operation.

The memory device 200 of the memory system 110 may include a plurality of memory blocks 210, a control circuit 220, a voltage supply unit 230, a row decoder 240, a page buffer 250, and a column decoder 260. The memory device 200 may be the nonvolatile memory device, for example the flash memory device. The flash memory device may have a 3-dimensional (3D) stacked structure.

Each of the memory blocks 210 may include a plurality of pages. Each of the pages may include a plurality of memory cells to which a plurality of word lines (WL) are electrically coupled.

The control circuit 220 may control various operations of the memory device 200 such as program, erase, and read operations.

The voltage supply unit 230 may provide word lines voltages, for example, a program voltage, a read voltage, and a pass voltage, to the respective word lines according to an operation mode, and may provide a voltage to be supplied to a bulk, for example, a well region, in which the memory cells are formed. A voltage generating operation of the voltage supply circuit 230 may be performed under control of the control logic 220. The voltage supply unit 230 may generate a plurality of variable read voltages for generation of a plurality of read data.

The row decoder 240 may select one of the memory blocks or sectors of the memory cell array 210, and may select one among the word lines of the selected memory block under the control of the control logic 220. The row decoder 240 may provide the word line voltage generated from the voltage supply circuit 230 to selected word lines or non-selected word lines under the control of the control logic 220.

During the program operation, the page buffer 250 may operate as a write driver for driving the bit lines according to data to be stored in the memory block 210. During the program operation, the page buffer 250 may receive the data to be written in the memory block 210 from a buffer (not illustrated), and may drive the bit lines according to the input data. The page buffer 250 may be formed of a plurality of page buffers (PB) 251 corresponding to the columns or the bit lines, or column pairs or bit line pairs, respectively. A plurality of latches may be included in each of the plurality of page buffers 251.

The controller 120 of the memory system 110 may control the memory device 200 in response to a request from the host 100. The controller 120 may provide the data read from the memory device 200, to the host 100, and store the data from the host 100 into the memory device 200. To this end, the controller 120 may control overall operations of the memory device 200, such as read, write, program and erase operations.

The controller 120 may include a host interface unit 130, a processor 140, an error correction code (ECC) unit 160, a power management unit (PMU) 170, a NAND flash controller (NFC) 180, and a memory 190.

The host Interface 130 may process a command and data from the host 100 and may communicate with the host 100 through at least one of various interface protocols such as a universal serial bus (USB), a multi-media card (MMC), a peripheral component interconnect express (PCI-E), a serial-attached SCSI (SAS), a serial advanced technology attachment (SATA), a parallel advanced technology attachment (PATA), a small computer system interface (SCSI), an enhanced small disk interface (ESDI), an integrated drive electronics (IDE), and the like.

The ECC unit 160 may detect and correct errors in data read from the memory device 200 during the read operation. The ECC unit 160 may perform the ECC decoding on the data read from the memory device 200, determine whether the ECC decoding succeeds, output an instruction signal according to the determination result, and correct error bits of the read data using parity bits generated during the ECC encoding. The ECC unit 160 may not correct error bits when the number of the error bits is greater than or equal to a threshold number of correctable error bits, and may output an error correction fail signal indicating failure in correcting the error bits.

The ECC unit 160 may perform an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a block coded modulation (BCM), and the like. The ECC unit 160 may include all circuits, systems or devices for the error correction operation.

The PMU 170 may provide and manage power for the controller 120, for example, power for the component elements included in the controller 120.

The NFC 180 may serve as a memory interface between the controller 120 and the memory device 200 to allow the controller 120 to control the memory device 200 in response to a request from the host 100. The NFC 180 may generate control signals for the memory device 200 and process data under the control of the processor 140 when the memory device 150 is a flash memory and, in particular, when the memory device 150 is a NAND flash memory.

The memory 190 may serve as a working memory of the memory system 110 and the controller 120, and store data for driving the memory system 110 and the controller 120. The controller 120 may control the memory device 200 in response to a request from the host 100. For example, the controller 120 may provide the data read from the memory device 200 to the host 100, and may store the data provided from the host 100 in the memory device 200. When the controller 120 controls the operations of the memory device 200, the memory 190 may store data used by the controller 120 and the memory device 200 for such operations as read, write, program and erase operations.

The memory 190 may be implemented with a volatile memory. For example, the memory 144 may be implemented with a static random access memory (SRAM) or a dynamic random access memory (DRAM). As described above, the memory 190 may store data used by the host 100 and the memory device 200 for the write and read operations. To store data, the memory 190 may include a program memory, a data memory, a write buffer, a read buffer, a map buffer, and the like.

Additionally, the memory 190 may store data for operations between the ECC unit 160 and the processor 140, such as data that is read during read operations. That is, the memory 190 may store data read from the semiconductor memory device 200. The data may include user data, parity data and status data. The status data may include information of which cycling group is applied to the memory block 210 of the semiconductor memory device 200 during the program operation.

The processor 140 may control general operations of the memory system 110, and a write operation or a read operation for the memory device 200, in response to a write request or a read request from the host 100. The processor 140 may drive firmware, which is referred to as a flash translation layer (FTL), to control the general operations of the memory system 110. The processor 140 may be implemented with a microprocessor or a central processing unit (CPU).

A management unit (not shown) may be included in the processor 140, and may perform bad block management of the memory device 200. The management unit may find bad memory blocks included in the memory device 200, which are in unsatisfactory condition for further use, and perform bad block management on the bad memory blocks. When the memory device 200 is a flash memory, for example, a NAND flash memory, a program failure may occur during the write operation, for example, during the program operation, due to characteristics of a NAND logic function. During the bad block management, the data of the program-failed memory block or the bad memory block may be programmed into a new memory block. Also, the bad blocks due to the program fail seriously deteriorates the utilization efficiency of the memory device 200 having a 3D stack structure and the reliability of the memory system 110, and thus reliable bad block management is required.

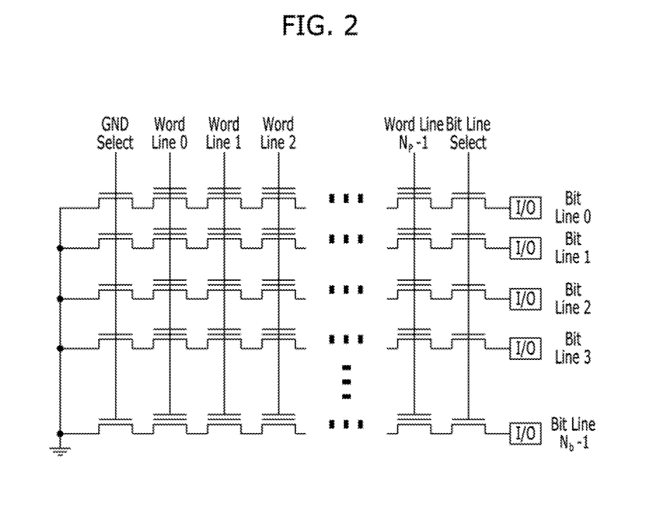

FIG. 2 is a diagram illustrating an example of a structure of a flash memory. Referring to FIG. 2, the flash memory may include a plurality of memory blocks. Each of the plurality of memory blocks may include a plurality of pages. Each of the plurality of pages may include a plurality of memory cells to which a plurality of word lines are electrically coupled. A block may include a plurality of word lines (Word Line 0 to Word Line Nₚ−1). The plurality of word lines may be coupled to a plurality of bit lines (Bit Line 0 to Bit Line N_{b}−1). The flash memory may include a plurality of memory blocks, as single level cell (SLC) memory blocks and multi-level cell (MLC) memory blocks, according to the number of bits which may be stored or expressed in each memory cell. The SLC memory block may include a plurality of pages which are implemented with memory cells, each memory cell being capable of storing 1-bit data. The MLC memory block may include a plurality of pages which are implemented with memory cells, each memory cell being capable of storing multi-bit data, for example, two or more-bit data. An MLC memory block including a plurality of pages which are implemented with memory cells that are each capable of storing 3-bit data may be defined as a triple level cell (TLC) memory block. The error correction code of the flash memory may correct errors of the cells on a single page basis.

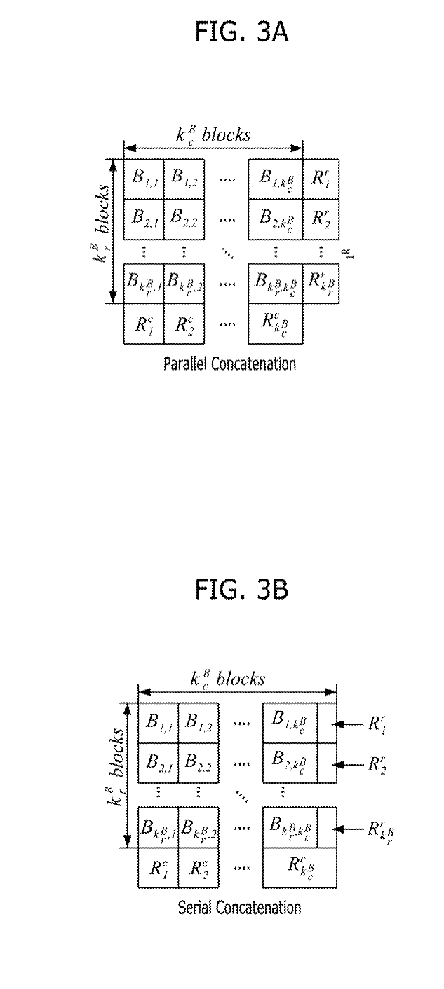

FIG. 3A is a diagram illustrating a block-wise concatenated Bose-Chaudhuri-Hocquenghem (BC-BCH) code that is concatenated in parallel, hereinafter referred to also as a parallel-concatenated BC-BCH code. FIG. 3B is a diagram Illustrating a BC-BCH code that is concatenated in series, hereinafter also referred to as a serial-concatenated BC-BCH code.

The block of the BC-BCH code may be different from the memory block. For example, the block of the BC-BCH code may be a bundle of bits, which are sequentially arranged in line. The configuration of the block of the BC-BCH code may differ. For example, the block of the BC-BCH code is illustrated as a square in FIGS. 3A and 38. The BC-BCH code may include a message block and a parity block, or may include a message-parity block in which the message block is combined with the parity block.

The BC-BCH code may include 2 kinds of the BCH constituent codes: a row BCH constituent code and a column BCH constituent code. The row BCH constituent code may be the same as the column BCH constituent code in the parallel-concatenated BC-BCH code.

In the serial-concatenated BC-BCH code, the row BCH constituent code may serve as an outer code and the column BCH constituent code may serve as an inner code. A single row BCH constituent code may share a single block of BC-BCH code with a single column BCH constituent code. A single row BCH constituent code may share a single block with each of the column BCH constituent codes. A single column BCH constituent code may share a single block with each of the row BCH constituent codes.

Both of the row BCH constituent code and the column BCH constituent code may be BCH codes. The row BCH constituent code may correct tᵣ bit-errors in nᵣ bits having kᵣ bits of a message to be protected and mᵣ parity bits. The column BCH constituent code may correct t_{c} bit-errors in n_{c} bits having k_{c} bits of a message to be protected and m_{c} parity bits. Hereinafter, it is assumed that the amount of data to be protected by the BC-BCH code is k, where k is a natural number.

Referring to FIG. 3A, the data may correspond to a message matrix the size of which is kᵣ^{B}×kᵣ^{B} of message blocks B_{i,j}. A single row BCH constituent code may include k_{c}^{B} message blocks and one or more parity blocks. A single column BCH constituent code may include kᵣ^{B} message blocks and one or more parity blocks.

For example, the BC-BCH code may include a plurality of message blocks, each of which is n_{B} bits. Referring to FIG. 3A, an i^{th} row BCH constituent code may include the message blocks of the i^{th} row and the parity blocks of the i^{th} row, as:

Cᵢ^{r}=[B_{i,1} . . . B_{i,k}_{ᵣ}_{^{B}}Rᵢ^{r}] (1)

Referring to FIG. 3A, j^{th} column BCH constituent code may include the message blocks of the j^{th} column and the parity blocks of the j^{th} column, as:

C_{jC}=[B_{1,j,} . . . Bₖ_{ᵣ}_{^{B}}_{,j,}Rⱼ^{c}] (2)

The message length of the row BCH constituent code may be as:

kᵣ=k/kᵣ^{B}=n_{B}×k_{c}^{B} (3)

The code length of the row BCH constituent code may be as:

nᵣ=kᵣ+mᵣ (4)

The message length of the column BCH constituent code may be as:

k_{c}=k/k_{c}^{B}=n_{B}×kᵣ^{B} (5)

The code length of the column BCH constituent code may be as:

n_{c}=k_{c}+m_{c} (6)

The code rate of the BC-BCH code may be as:

R=k/(k+mᵣkᵣ^{B}+m_{c}k_{c}^{B}) (7)

In the above case, a single message block may include n_{B}=k/(kᵣ^{B}×k_{c}^{B}) bits, which is the same as each of the other message blocks.

In order for row BCH constituent codes to have different sizes of message block from each other and for all the message blocks in a single row of BCH constituent code to have the same size, the i^{th} row BCH constituent code may include the message blocks of the i^{th} row and the parity blocks of the i^{th} row, as shown in Equation 1, and the j^{th} column BCH constituent code may include the message blocks of the j^{th} column and the parity blocks of the j^{th} column, as:

Cⱼ^{c}=[B_{1,f(j)}B_{2,f(j+1)} . . . Bₖ_{ᵣ}_{^{B}}_{,f(j+k}_{ᵣ}_{^{B}}₋₁₎Rⱼ^{c}], (8)

where f(x)={(x−1) mod k_{c}^{B}}+1

Referring to FIG. 3B, the data may be assigned to the message block, and the last block of each row BCH constituent code may be the parity block for the row BCH constituent code or the message-parity block for the row BCH constituent code. Except for the parity block for the column BCH constituent code, the message matrix may have the size of kᵣ^{B}×k_{c}^{B} and include the message blocks, the message-parity block for the row BCH constituent code, and an extra parity block in each row. A single row BCH constituent code may include k_{c}^{B}−1 message blocks and a single message-parity block. A single column BCH constituent code may include message blocks or the message-parity blocks kᵣ^{B} and a single parity block. The serial-concatenated BC-BCH code may be designed so that the row BCH constituent code may correct more errors than the column BCH constituent code may correct (tᵣ≦t_{c}).

For example, the serial-concatenated BC-BCH code may be designed so that each of the message blocks and the message-parity blocks may include n_{B} bits. Referring to FIG. 3B, i^{th} row BCH constituent code may include the message blocks and the parity blocks of the i^{th} row as in Equation 1.

Referring to FIG. 3B, j^{th} column BCH constituent code may include the message blocks and the parity blocks of a j^{th} column as:

Cⱼ^{c}=[B_{1,j,} . . . Bₖ_{ᵣ}_{^{B}}_{,j,}Rⱼ^{c}], for 1≦j≦k_{c}^{B} (9)

The j^{th} column BCH constituent code may include the message blocks and the parity blocks of j^{th} column as:

Cⱼ^{c}=[{B_{1,j}, R₁^{r}} . . . {Bₖ_{ᵣ}_{^{B}}_{,j}, Rₖ_{ᵣ}_{^{B}}^{r}}Rⱼ^{c}], where j=k_{c}^{B} (10)

The length of the message of the row BCH constituent code may be represented as:

kᵣ=k/kᵣ^{B} (11)

The length of the code of the row BCH constituent code may be represented as:

nᵣ=kᵣ+mᵣ=n_{B}×k_{c}^{B} (12)

The length of the message of the column BCH constituent code may be represented as:

k_{c}=n_{B}×kᵣ^{B} (13)

The length of the code of the column BCH constituent code may be represented as shown in Equation 6.

The code rate of the serial-concatenated BC-BCH code may be represented in Equation 7.

In the serial-concatenated BC-BCH code, each of the message blocks and the message-parity blocks has the same number of bits, which is represented as:

n_{B}=(k+mᵣ×kᵣ^{B})/(kᵣ^{B}×k_{c}^{B})=nᵣ/k_{c}^{B},

In order for row BCH constituent codes to have different sizes of message block from each other and for all the message blocks in a single row BCH constituent code to have the same size, the row BCH constituent code and the column BCH constituent code may be represented similarly to the above-described Equations 1 and 8, respectively.

For convenience of illustration, only a parallel-concatenated BC-BCH code will be described hereinafter. However, a serial-concatenated BC-BCH code may be used as well.

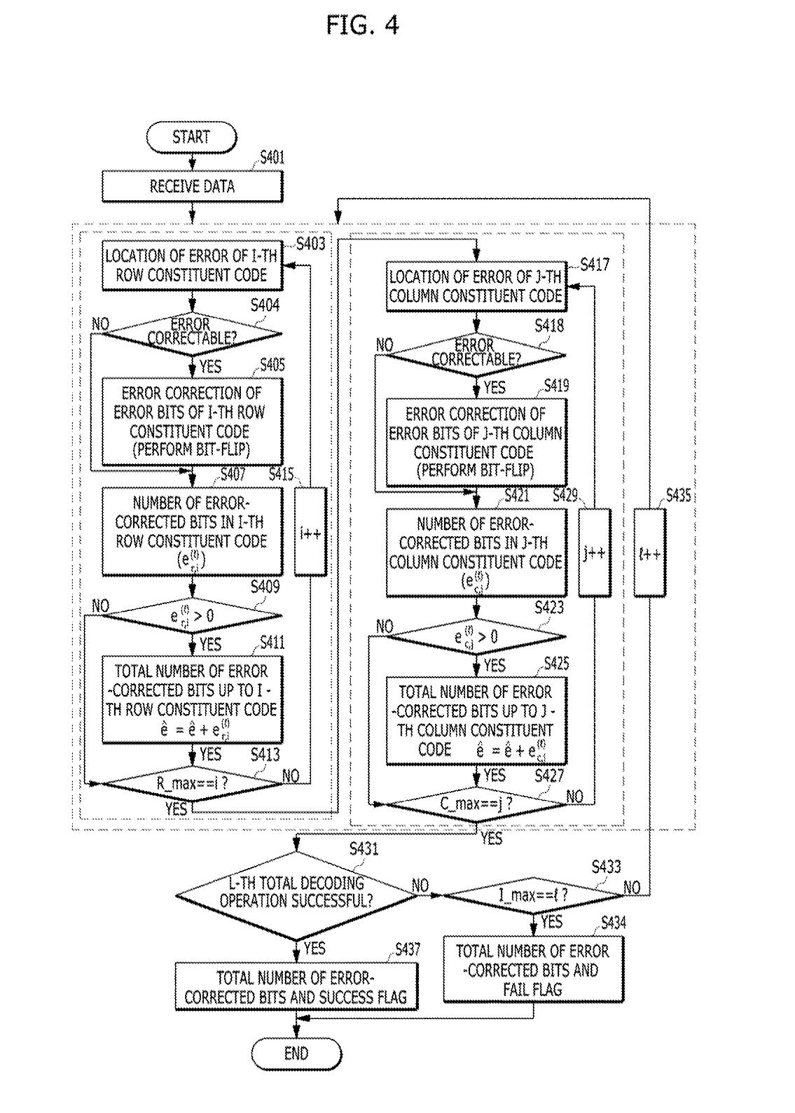

FIG. 4 is a flowchart Illustrating an operation of a flash memory system according to a first embodiment. The operation may be performed by controller 120 of FIG. 1.

FIG. 4 shows an example of an operation obtaining a total number (ê) of error-corrected data bits during a decoding operation to the data.

The data comprises the block-wise concatenated BCH code. The block-wise concatenated BCH code comprises two kinds of constituent codes, a row constituent code and a column constituent code, respectively.

The decoding operation to the data may be performed by firstly setting the number (I_max) of the total decoding operations, and then sequentially performing the l-th total decoding operation as many times as the number (I_max) of the total decoding operations. Further, during each decoding operation, a predetermined decoding operation to the row constituent code and a predetermined decoding operation to the column constituent code may be performed. According to the first embodiment, the decoding operation may be performed first to the row constituent code and then to the column constituent code. In an alternative, the decoding operation may be performed first to the column constituent code and then to the row constituent code.

The predetermined decoding operation to the row constituent code may be performed as many times as a predetermined number (R_max) of the row constituent code of the data. The predetermined decoding operation to the column constituent code may be performed as many times as a predetermined number (C_max) of the column constituent code of the data.

The operation of obtaining the total number (ê) of error-corrected bits, according to the first embodiment, may be expressed as:

ê=Σₗ₌₀{Σᵢe_{r,i}^{(l)}1_{r,i}^{(l)}+Σᵢe_{c,j}^{(l)}1_{c,j}^{(l)}} (14)

Referring to FIG. 4, at step S401, the controller 120 may receive data from the non-volatile memory device 200. The data may be BCH data comprising the row constituent code and the column constituent code of the BCH constituent code. Hereinafter, for the convenience of the description, the BCH data provided from the non-volatile memory device 200 may also be referred to simply as data.

At step S403, the controller 120 may obtain an error location of i-th row constituent code of the data. The error location of the i-th row constituent code of the data may be obtained through the error location (or locator) polynomial (ELP) using the syndrome value obtained from the syndrome calculation. The error location (or locator) polynomial (ELP) may be generated through the key-equation solver. The key-equation solver may use the Berlekamp-Massey (BM) algorithm or the Euclidean algorithm. The controller 120 may obtain the error locations and a number of error bits through the error location (or locator) polynomial (ELP). That is, the controller 120 may obtain an error polynomial through the Chien search algorithm based on the error location (or locator) polynomial (ELP). Coefficients of the error polynomial represent the error locations of the i-th row constituent code of the data.

At step S404, the controller 120 may determine whether the error bits corresponding to the error locations of the i-th row constituent code can be corrected.

Hence, when the error bits corresponding to the error locations of the i-th row constituent code cannot be corrected, step S407 may be performed. When the error bits corresponding to the error locations of the i-th row constituent code can be corrected, step S405 may be performed.

At step S405, the controller 120 may perform a bit-flip operation in order to correct the error bits corresponding to the error locations of the i-th row constituent code of the data. That is, the controller 120 may perform the error correction operation by bit-flipping bit values of the error bits corresponding to the error locations.

At step S407, the controller 120 may obtain a number (e_{r,i}^{(l)}) of error-corrected bits of the i-th row constituent code. When the error bits of the i-th row constituent code are error-corrected through the bit-flip operation at step S405, the controller 120 may obtain the number (e_{r,i}^{(l)}) of error-corrected bits of the i-th row constituent code. Hereinafter, for the convenience of the description, the number (e_{r,i}^{(l)}) of error-corrected bits in the i-th row constituent code of the data is referred to as number (e_{r,i}^{(l)}) of error-corrected bits in the i-th row constituent code.

When the error bits corresponding to the error locations of the i-th row constituent code cannot be corrected as the determination result of step S404, the number (e_{r,i}^{(l)}) of error-corrected bits in the i-th row constituent code is zero (‘0’) since there is no error-corrected bit due to decoding failure.

At step S409, the controller 120 may determine whether the number (e_{r,i}^{(l)}) of error-corrected bits in the i-th row constituent code obtained through steps S403 to S407 is greater than or equal to one (1_{r,i}^{(l)})) or whether there are one or more error-corrected bits through steps S403 to S407 (“e_{r,i}^{(l)}>0”).

When the number (e_{r,i}^{(l)}) of error-corrected bits in the i-th row constituent code obtained through steps S403 to S407 is not greater than or equal to one (1_{r,i}^{(l)}) as the determination result of step S409 (“NO”), step S413 may be performed.

When the number (e_{r,i}^{(l)}) of error-corrected bits in the i-th row constituent code obtained through steps S403 to S407 is greater than or equal to one (1_{r,i}^{(l)}) as the determination result of step S409 (“YES”), the controller 120 may obtain and may store the total number (ê) of error-corrected bits to the i-th row constituent code in a buffer at step S411. The buffer may be a single buffer, and may store the total number (ê) of error-corrected bits obtained during the predetermined entire decoding operations.

The total number (ê) of error-corrected bits may be updated whenever the decoding operation up to the row or column constituent code is performed, and may be stored in the buffer. Therefore, the total number (ê) of error-corrected bits includes the number of error-corrected bits obtained during the decoding operations to the row constituent code and the column constituent code.

The total number (ê) of error-corrected bits up to the i-th row constituent code may be expressed as equation 15.

ê=ê+e_{r,i}^{(l)} (5)

The total number (ê) of error-corrected bits up to the i-th row constituent code may be obtained by adding the number (e_{r,i}^{(l)}) of error-corrected bits in the i-th row constituent code to the total number (ê) stored in the buffer, which is the total number (ê) of error-corrected bits up to the (i−1)th row constituent code. The obtained total number (ê) of error-corrected bits up to the i-th row constituent code may be stored in the buffer by updating the total number (ê) stored in the buffer. When the total number (ê) stored in the buffer is zero (‘0’) as an initial value, the number (e_{r,i}^{(l)}) of error-corrected bits in the i-th row constituent code is stored in the buffer as the total number (ê) of error-corrected bits up to the i-th row constituent code.

At step S413, the controller 120 may determine whether the i-th row constituent code, to which the decoding operation is performed, is the last row constituent code corresponding to the predetermined number (R_max) of the row constituent codes.

When the i-th row constituent code, to which the decoding operation is performed, is not the last row constituent code corresponding to the predetermined number (R_max) of the row constituent codes as the determination result of step S413 (“NO”), the controller 120 increases the index of the row constituent code (“i++”) at step S415 for the decoding operation to (i+1)th row constituent code and repeats steps S403 to S413 until current row constituent code, to which the decoding operation is performed, is the last row constituent code corresponding to the predetermined number (R_max) of the row constituent codes.

When the i-th row constituent code, to which the decoding operation is performed, is the last row constituent code corresponding to the predetermined number (R_max) of the row constituent codes as the determination result of step S413 (“YES”), the controller 120 may perform step S417 for the decoding operation to the column constituent code.

At step S417, the controller 120 may obtain an error location of j-th column constituent code of the data. The error location of the j-th column constituent code of the data may be obtained through the error location (or locator) polynomial (ELP) using the syndrome value obtained from the syndrome calculation. The error location (or locator) polynomial (ELP) may be generated through the key-equation solver. The key-equation solver may use the Berlekamp-Massey (BM) algorithm or the Euclidean algorithm. The controller 120 may obtain the error locations and a number of error bits through the error location (or locator) polynomial (ELP). That is, the controller 120 may obtain an error polynomial through the Chien search algorithm based on the error location (or locator) polynomial (ELP). Coefficients of the error polynomial represent the error locations of the j-th column constituent code of the data.

At step S418, the controller 120 may determine whether the error bits corresponding to the error locations of the j-th column constituent code can be corrected.

When the error bits corresponding to the error locations of the j-th column constituent code cannot be corrected, step S421 may be performed.

When the error bits corresponding to the error locations of the j-th column constituent code can be corrected, step S419 may be performed.

At step S419, the controller 120 may perform bit-flip operation in order to correct the error bits corresponding to the error locations of the j-th column constituent code of the data. For example, the controller 120 may perform the error correction operation by bit-flipping bit values of the error bits corresponding to the error locations.

At step S421, the controller 120 may obtain a number (e_{c,j}^{(l)}) of error-corrected bits of the j-th column constituent code. When the error bits of the j-th column constituent code are error-corrected through the bit-flip operation at step S419, the controller 120 may obtain the number (e_{c,j}^{(l)}) of error-corrected bits of the j-th column constituent code. Hereinafter, for convenience, the number (e_{c,j}^{(l)}) of error-corrected bits in the j-th column constituent code of the data may be referred to as number (e_{c,j}^{(l)}) of error-corrected bits in the j-th column constituent code.

When the error bits corresponding to the error locations of the j-th column constituent code cannot be corrected, the number (e_{c,j}^{(l)}) of error-corrected bits in the j-th column constituent code is zero (‘0’) since there is no error-corrected bit due to decoding failure.

At step S423, the controller 120 may determine whether the number (e_{c,j}^{(l)}) of error-corrected bits in the j-th column constituent code obtained through steps S417 to S421 is greater than or equal to one (1_{c,j}^{(l)}) or whether there are one or more error-corrected bits through steps S417 to S421 (“e_{c,j}^{(l)}>0”).

When the number (e_{c,j}^{(l)}) of error-corrected bits in the j-th column constituent code obtained through steps S417 to S421 is not Greater than or equal to one (1_{c,j}^{(l)}) as the determination result of step S423 (“NO”), step S427 may be performed.

When the number (e_{c,j}^{(l)}) of error-corrected bits in the j-th column constituent code obtained through steps S417 to S421 is greater than or equal to one (1_{c,j}^{(l)}) as the determination result of step S423 (“YES”), the controller 120 may obtain and may store the total number (ê) of error-corrected bits to the j-th column constituent code in a buffer at step S425. The buffer may store sum of the total number of error-corrected bits obtained during the predetermined entire decoding operations to the entire row constituent codes through steps S403 to S415 and the total number of error-corrected bits obtained through the predetermined entire decoding operations up to (j−1)th column constituent codes, as the total number (ê) of error-corrected bits.

The total number (ê) of error-corrected bits up to the j-th column constituent code may be expressed as equation 16.

ê=ê+e_{c,j}^{(l)} (16)

The total number (ê) of error-corrected bits up to the j-th column constituent code may be obtained by adding the number (e_{c,j}^{(l)}) of error-corrected bits in the j-th column constituent code to the total number (ê) stored in the buffer, which is the sum of the total number of error-corrected bits obtained during the predetermined entire decoding operations to the entire row constituent codes through steps S403 to S415 and the total number of error-corrected bits obtained through the predetermined entire decoding operations up to (j−1)th column constituent codes. The obtained total number (ê) of error-corrected bits up to the j-th column constituent code may be stored in the buffer by updating the total number (ê) stored in the buffer.

At step S427, the controller 120 may determine whether the j-th column constituent code, to which the decoding operation may be performed, is the last column constituent code corresponding to the predetermined number (C_max) of the column constituent codes.

When the j-th column constituent code, to which the decoding operation may be performed, is not the last column constituent code corresponding to the predetermined number (C_max) of the column constituent codes as the determination result of step S427 (“NO”), the controller 120 increases the index of the column constituent code (“j++”) at step S429 for the decoding operation to (j+1)th column constituent code and repeats steps S417 to S427 until current column constituent code, to which the decoding operation may be performed, is the last column constituent code corresponding to the predetermined number (C_max) of the column constituent codes.

When the j-th column constituent code, to which the decoding operation may be performed, is the last column constituent code corresponding to the predetermined number (C_max) of the column constituent codes as the determination result of step S427 (“YES”), the controller 120 may perform step S431 for determining whether l-th total decoding operation is successful.

When the l-th total decoding operation is successful as the determination result of step S431 (“YES”), the controller 120 transmits the total number (ê) of error-corrected bits up to the l-th total decoding operation and the success flag to the host 100 without performing remaining total decoding operation among the total decoding operations of the total number (I_max) at step S437. It is possible to estimate total number of error-corrected bits of the data through the total number (ê) of error-corrected bits up to the l-th total decoding operation, and thus to estimate the channel condition of the non-volatile memory device 200.

When the l-th total decoding operation is not successful as the determination result of step S431 (“NO”), the controller 120 may determine whether the number of total decoding operations up to the l-th total decoding operation is the same as the total number (I_max) of the total decoding operations at step S433.

When the number of total decoding operations up to the l-th total decoding operation is the same as the total number (Imax) of the total decoding operations as the determination result of step S433, the total number (I_max) of the total decoding operations is completed without success and thus the controller 120 transmits the total number (ê) of error-corrected bits up to the total number (I_max) of the total decoding operations and the fall flag to the host 100 at step S434.

When the number of total decoding operations up to the l-th total decoding operation is not the same as the total number (I_max) of the total decoding operations as the determination result of step S433, the controller 120 increases the index of the total decoding operation (“l++”) at step S435 for the next total decoding operation and repeats steps S403 to S433 until the number of total decoding operations up to the current total decoding operation is the same as the total number (I_max) of the total decoding operations.

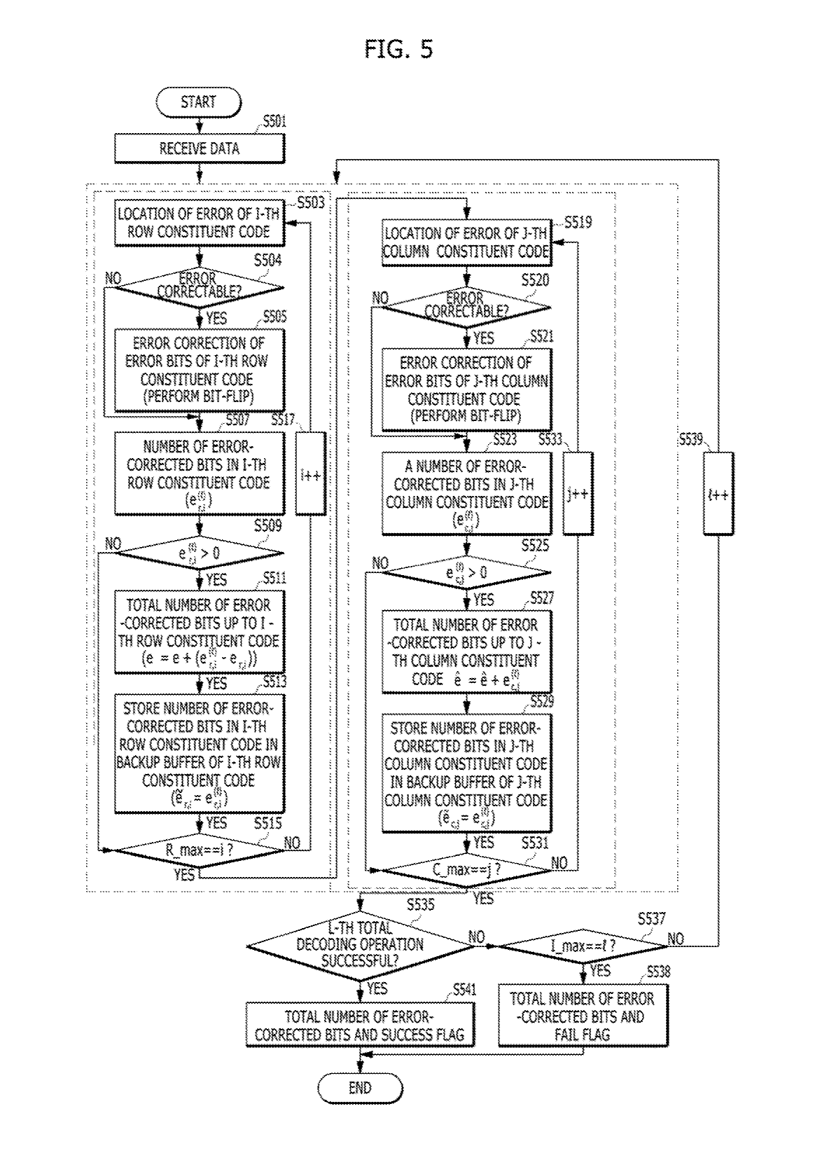

FIG. 5 is a flowchart illustrating an operation of a flash memory system according to a second embodiment. The operation may be performed by a controller 120 of FIG. 1.

The flow of FIG. 5 shows the operation of obtaining a total number (ê) of error-corrected bits for data during the decoding operation to the data.

The data comprises the block-wise concatenated BCH code. The block-wise concatenated BCH code comprises two kinds of constituent codes, which are referred to as a row constituent code and a column constituent code, respectively.

The decoding operation to the data may be performed by firstly setting the number (I_max) of the total decoding operations, and then sequentially performing the l-th total decoding operation as many times as the number (I_max) of the total decoding operations. Further, during each decoding operation of the number (I_max) of the total decoding operations, a predetermined decoding operation to the row constituent code and a predetermined decoding operation to the column constituent code may be performed. According to the second embodiment, the decoding operation may be performed first to the row constituent code and then to the column constituent code. In an alternative, the decoding operation may be performed first to the column constituent code and then to the row constituent code.

The predetermined decoding operation to the row constituent code may be performed as many times as a predetermined number (R_max) of the row constituent codes of the data. The predetermined decoding operation to the column constituent code may be performed as many times as a predetermined number (C_max) of the column constituent code of the data.

The operation of obtaining the total number (ê) of error-corrected bits according to the second embodiment may be expressed as:

ê=Σₗ₌₀{Σᵢ(e_{r,i}^{(l)}−e_{r,i}^{˜(l)})1_{r,i}^{(l)}+Σᵢ(e_{c,j}^{(l)}−e_{c,j}^{˜(l)})1_{c,j}^{(l)}} (17)

Referring to FIG. 5, steps S501 to S507 for obtaining the number (e_{r,i}^{(l)}) of error-corrected bits in the l-th row constituent code are the same as steps S401 to S407 described with reference to FIG. 4 and thus description for steps S501 to S507 is omitted.

At step S509, the controller 120 may determine whether the number (e_{r,i}^{(l)}) of error-corrected bits in the i-th row constituent code obtained through steps S503 to S507 is greater than or equal to one (1_{r,i}^{(l)}) or whether there are one or more error-corrected bits through steps S503 to S507 (“e_{r,i}^{(l)}>0”).

When the number (e_{r,i}^{(l)}) of error-corrected bits in the i-th row constituent code obtained through steps S503 to S507 is not greater than or equal to one (1_{r,i}^{(l)}) as the determination result of step S509 (“NO”), step S515 may be performed.

When the number (e_{r,i}^{(l)}) of error-corrected bits in the i-th row constituent code obtained through steps S503 to S507 is greater than or equal to one (1_{r,i}^{(l)}) as the determination result of step S509 (“YES”), the controller 120 may obtain and may store the total number (ê) of error-corrected bits to the i-th row constituent code in a buffer at step S511. The total number (ê) of error-corrected bits up to the l-th row constituent code may be expressed as:

ê=ê+(e_{r,i}^{(l)}−e_{r,i}^{˜}) (18)

In equation 18, e_{r,i}^{˜} denotes the number of error-corrected bits in the i-th row constituent code obtained through the decoding operation to the i-th row constituent code during the (l−1)th total decoding operation. An initial value of the number (e_{r,i}^{˜}) of error-corrected bits in the i-th row constituent code is zero (‘0’). Hereinafter, for the convenience of the description, the number (e_{r,i}^{˜}) of error-corrected bits in the i-th row constituent code is referred to as backup number (e_{r,i}^{˜}) of error-corrected bits in the i-th row constituent code. The backup number (e_{r,i}^{˜}) of error-corrected bits in the i-th row constituent code may be stored in a backup buffer of the i-th row constituent code.

The total number (ê) of error-corrected bits up to the l-th row constituent code during the l-th total decoding operation may be obtained by subtracting the backup number (e_{r,i}^{˜}) of error-corrected bits in the i-th row constituent code from the number (e_{r,i}^{˜}) of error-corrected bits in the l-th row constituent code and then adding the subtraction result to the total number (ê) stored in the buffer, which is the total number (ê) of error-corrected bits up to the (i−1)th row constituent code. The reason of subtracting the backup number (e_{r,i}^{˜}) of error-corrected bits in the i-th row constituent code from the number (e_{r,i}^{(l)}) of error-corrected bits in the i-th row constituent code is because the error bits of the i-th row constituent code may be repeatedly error-corrected and the repeated error-correction of the error bit may affect the process of obtaining the total number (ê) of error-corrected bits and thus may make it hard to estimate the channel condition of the non-volatile memory device 200.

At step S513, the controller 120 may store the number (e_{r,i}^{(l)}) of error-corrected bits in the l-th row constituent code obtained at step S507 in the backup buffer of the i-th row constituent code as the backup number (e_{r,i}^{˜}) of error-corrected bits in the i-th row constituent code for obtaining the total number of error-corrected bits up to the i-th row constituent code through the decoding operation to the i-th row constituent code during (l+1)th total decoding operation.

At step S515, the controller 120 may determine whether the i-th row constituent code, to which the decoding operation is performed, is the last row constituent code corresponding to the predetermined number (R_max) of the row constituent codes. When the i-th row constituent code, is not the last row constituent code corresponding to the predetermined number (R_max) of the row constituent codes as the determination result of step S515 (“NO”), the controller 120 increases the index of the row constituent code (“i++”) at step S517 for the decoding operation to (i+1)th row constituent code and repeats steps S503 to S515 until current row constituent code, to which the decoding operation is performed, is the last row constituent code corresponding to the predetermined number (R_max) of the row constituent codes.

When the i-th row constituent code, is the last row constituent code corresponding to the predetermined number (R_max) of the row constituent codes as the determination result of step S515 (“YES”), the controller 120 may perform step S519 for the decoding operation to the column constituent code.

Steps S519 to S523 for obtaining the number (e_{c,j}^{(l)}) of error-corrected bits in the j-th column constituent code are the same as steps S417 to S421 described with reference to FIG. 4 and thus description for steps S519 to S523 is omitted.

At step S525, the controller 120 may determine whether the number (e_{c,j}^{(l)}) of error-corrected bits in the j-th column constituent code obtained through steps S517 to S521 is greater than or equal to one (1_{c,j}^{(l)}) or whether there are one or more error-corrected bits through steps S517 to S521 (“e_{c,j}^{(l)}>0”).

When the number (e_{c,j}^{(l)}) of error-corrected bits in the j-th column constituent code obtained through steps S517 to S521 is not greater than or equal to one (1_{c,j}^{(l)}) as the determination result of step S525 (“NO”), step S531 may be performed.

When the number (e_{c,j}^{(l)}) of error-corrected bits in the j-th column constituent code obtained through steps S517 to S521 is greater than or equal to one (1_{c,j}^{(l)}) as the determination result of step S525 (“YES”), the controller 120 may obtain and may store the total number (ê) of error-corrected bits to the j-th column constituent code in the buffer at step S527. The total number (ê) of error-corrected bits up to the j-th column constituent code may be expressed as:

ê=ê+(e_{c,j}^{(l)}−e_{c,j}^{˜}) (19)

In equation 19, e_{c,j}^{˜} denotes the number of error-corrected bits in the j-th column constituent code obtained through the decoding operation to the j-th column constituent code during the (l−1)th total decoding operation. An initial value of the number (e_{c,j}^{˜}) of error-corrected bits in the j-th column constituent code is zero (‘O’). Hereinafter, for convenience, the number (e_{c,j}^{˜}) of error-corrected bits in the j-th column constituent code may be referred to as backup number (e_{c,j}^{˜}) of error-corrected bits in the j-th column constituent code. The backup number (e_{c,j}^{˜}) of error-corrected bits in the j-th column constituent code may be stored in a backup buffer of the j-th column constituent code.

The total number (ê) of error-corrected bits up to the j-th column constituent code during the l-th total decoding operation may be obtained by subtracting the backup number (e_{c,j}^{˜}) of error-corrected bits in the j-th column constituent code from the number (e_{c,j}^{(l)}) of error-corrected bits in the j-th column constituent code and then adding the subtraction result to the total number (ê) stored in the buffer, which is the total number (ê) of error-corrected bits up to the (j−1)th column constituent code. The reason of subtracting the backup number (e_{c,j}^{˜}) of error-corrected bits in the j-th column constituent code from the number (e_{c,j}^{(l)}) of error-corrected bits in the j-th column constituent code is because the error bits of the j-th column constituent code may be repeatedly error-corrected and the repeated error-correction of the error bit may affect the process of obtaining the total number (ê) of error-corrected bits and thus may make it hard to estimate the channel condition of the non-volatile memory device 200.

At step S529, the controller 120 may store the number (e_{c,j}^{(l)}) of error-corrected bits in the j-th column constituent code obtained at step S523 in the backup buffer of the j-th column constituent code as the backup number (e_{c,j}^{˜}) of error-corrected bits in the j-th column constituent code for obtaining the total number of error-corrected bits up to the j-th column constituent code through the decoding operation to the j-th column constituent code during (l+1)th total decoding operation.

At step S531, the controller 120 may determine whether the j-th column constituent code, to which the decoding operation is performed, is the last column constituent code corresponding to the predetermined number (C_max) of the column constituent codes.

When the j-th column constituent code, is not the last column constituent code corresponding to the predetermined number (C_max) of the column constituent codes as the determination result of step S531 (“NO”), the controller 120 increases the index of the column constituent code (“j++”) at step S539 for the decoding operation to (j+1)th column constituent code and repeats steps S519 to S531 until current column constituent code, to which the decoding operation is performed, is the last column constituent code corresponding to the predetermined number (C_max) of the column constituent codes.

When the j-th column constituent code, to which the decoding operation is performed, is the last column constituent code corresponding to the predetermined number (C_max) of the column constituent codes as the determination result of step S531 (“YES”), the controller 120 may perform step S535 for determining whether the l-th total decoding operation is successful.

When the l-th total decoding operation is successful as the determination result of step S535 (“YES”), the controller 120 transmits the total number (ê) of error-corrected bits up to the l-th total decoding operation and the success flag to the host 100 without performing remaining total decoding operation among the total decoding operations of the total number (I_max) at step S541. It Is possible to estimate total number of error-corrected bits of the data through the total number (ê) of error-corrected bits up to the l-th total decoding operation, and thus to estimate the channel condition of the non-volatile memory device 200.

When the l-th total decoding operation is not successful as the determination result of step S535 (“NO”), the controller 120 may determine whether the number of total decoding operations up to the l-th total decoding operation is the same as the total number (I_max) of the total decoding operations at step S537.

When the number of total decoding operations up to the l-th total decoding operation is the same as the total number (I_max) of the total decoding operations as the determination result of step S537, the total number (I_max) of the total decoding operations is completed without success and thus the controller 120 transmits the total number (ê) of error-corrected bits up to the total number (I_max) of the total decoding operations and the fail flag to the host 100 at step S538.

When the number of total decoding operations up to the l-th total decoding operation is not the same as the total number (I_max) of the total decoding operations as the determination result of step S537, the controller 120 increases the index of the total decoding operation (“l++”) at step S539 for the next total decoding operation and repeats steps S503 to S537 until the number of total decoding operations up to the current total decoding operation is the same as the total number (I_max) of the total decoding operations.

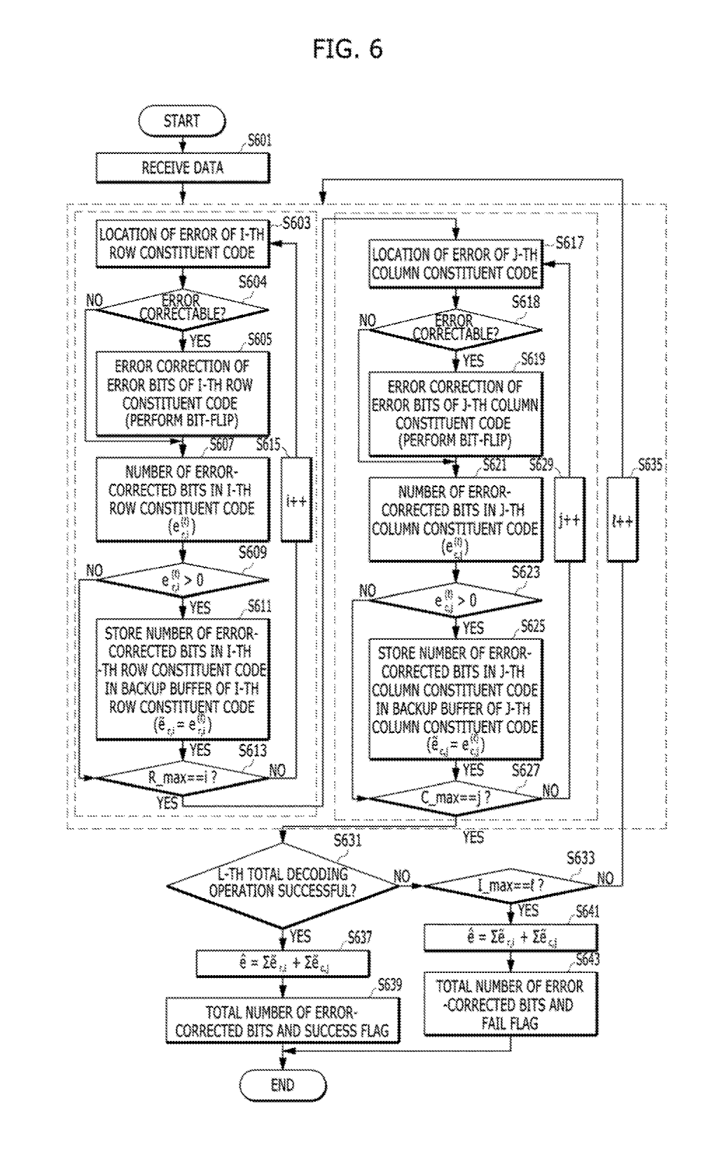

FIG. 6 is a flowchart illustrating an operation of a flash memory system according to a third embodiment. The operation may be performed by a controller 120 of FIG. 1.

The flow of FIG. 6 shows the operation of obtaining a total number (ê) of error-corrected bits for data during the decoding operation to the data.

The decoding operation to the data may be performed by firstly setting total number (I_max) of the total decoding operations, and then sequentially performing the l-th total decoding operation as many times as the total number (I_max) of the total decoding operations. Further, during each decoding operation of the total number (I_max) of the total decoding operations, a predetermined decoding operation to the row constituent code and a predetermined decoding operation to the column constituent code may be sequentially performed as many times as a predetermined number (R_max) of the row constituent codes of the data and a predetermined number (C_max) of the column constituent code of the data, respectively.

The third embodiment is another method of obtaining the same result as the second embodiment described with reference to FIG. 5.

The operation of obtaining the total number (ê) of error-corrected bits according to the third embodiment may be expressed as:

ê=Σᵢ(e_{r,i}^{˜})+Σⱼ(e_{c,j}^{˜}) (20)

Referring to FIG. 6, steps S601 to S607 for obtaining the number (e_{r,i}^{(l)}) of error-corrected bits in the i-th row constituent code are the same as steps S401 to S407 described with reference to FIG. 4 and thus description for steps S501 to S507 is omitted.

At step S609, the controller 120 may determine whether the number (e_{r,i}^{(l)}) of error-corrected bits in the i-th row constituent code obtained through steps S603 to S607 is greater than or equal to one (1_{r,i}^{(l)}) or whether there are one or more error-corrected bits through steps S603 to S607 (“e_{r,i}^{(l)}>0”).

When the number (e_{r,i}^{(l)}) of error-corrected bits in the i-th row constituent code obtained through steps S603 to S607 is not greater than or equal to one (1_{r,i}^{(l)}) as the determination result of step S609 (“NO”), step S613 may be performed.

When the number (e_{r,i}^{(l)}) of error-corrected bits in the l-th row constituent code obtained through steps S603 to S607 is greater than or equal to one (1_{r,i}^{(l)}) as the determination result of step S609 (“YES”), the controller 120 may store the number (e_{r,i}^{(l)}) of error-corrected bits in the i-th row constituent code in a backup buffer in order to back-up the number (e_{r,i}^{(l)}) of error-corrected bits in the i-th row constituent code at step S611. Hereinafter, for convenience, the number (e_{r,i}^{(l)}) of error-corrected bits in the i-th row constituent code stored in the backup buffer may be referred to as backup number (e_{r,i}^{˜}) of error-corrected bits in the i-th row constituent code. The controller 120 may delete the backup number (e_{r,i}^{˜}) of error-corrected bits in the l-th row constituent code obtained during the (l−1)th total decoding operation, and may store the backup number (e_{r,i}^{˜}) of error-corrected bits in the i-th row constituent code obtained during l-th total decoding operation as updated backup number (e_{r,i}^{˜}) of error-corrected bits in the i-th row constituent code.

At step S613, the controller 120 may determine whether the i-th row constituent code, to which the decoding operation is performed, is the last row constituent code corresponding to the predetermined number (R_max) of the row constituent codes.

When the i-th row constituent code is not the last row constituent code corresponding to the predetermined number (R_max) of the row constituent codes as the determination result of step S613 (“NO”), the controller 120 increases the index of the row constituent code (“i++”) at step S615 for the decoding operation to (i+1)th row constituent code and repeats steps S603 to S613 until current row constituent code, to which the decoding operation is performed, is the last row constituent code corresponding to the predetermined number (R_max) of the row constituent codes.

When the i-th row constituent code, to which the decoding operation is performed, is the last row constituent code corresponding to the predetermined number (R_max) of the row constituent codes as the determination result of step S613 (“YES”), the controller 120 may perform step S617 for the decoding operation to the column constituent code.

Steps S617 to S621 for obtaining the number (e_{c,j}^{(l)}) of error-corrected bits in the j-th column constituent code are the same as steps S417 to S421 described with reference to FIG. 4 and thus description for steps S617 to S621 is omitted.

At step S623, the controller 120 may determine whether the number (e_{c,j}^{(l)}) of error-corrected bits in the j-th column constituent code obtained through steps S617 to S621 is greater than or equal to one (1_{c,j}^{(l)}) or whether there are one or more error-corrected bits through steps S617 to S621 (“e_{c,j}^{(l)}>0”).

When the number (e_{c,j}^{(l)}) of error-corrected bits in the j-th column constituent code obtained through steps S617 to S621 is not greater than or equal to one (1_{c,j}^{(l)}) as the determination result of step S623 (“NO”), step S627 may be performed.

When the number (e_{c,j}^{(l)}) of error-corrected bits in the j-th column constituent code obtained through steps S617 to S621 is greater than or equal to one (1_{c,j}^{(l)}) as the determination result of step S623 (“YES”), the controller 120 may store the number (e_{c,j}^{(l)}) of error-corrected bits in the j-th column constituent code in a backup buffer in order to back-up the number (e_{c,j}^{(l)}) of error-corrected bits in the j-th column constituent code at step S625. Hereinafter, for convenience, the number (e_{c,j}^{(l)}) of error-corrected bits in the j-th column constituent code stored in the backup buffer may be referred to as backup number (e_{c,j}^{˜}) of error-corrected bits in the j-th column constituent code. The controller 120 may delete the backup number (e_{c,j}^{˜}) of error-corrected bits in the j-th column constituent code obtained during (l−1)th total decoding operation, and may store the backup number (e_{c,j}^{˜}) of error-corrected bits in the j-th column constituent code obtained during l-th total decoding operation as updated backup number (e_{c,j}^{˜}) of error-corrected bits in the j-th column constituent code.

At step S627, the controller 120 may determine whether the j-th column constituent code, to which the decoding operation is performed, is the last column constituent code corresponding to the predetermined number (C_max) of the column constituent codes.

When the j-th column constituent code, to which the decoding operation is performed, is not the last column constituent code corresponding to the predetermined number (C_max) of the column constituent codes as the determination result of step S627 (“NO”), the controller 120 increases the index of the column constituent code (“j++”) at step S629 for the decoding operation to (j+1)th column constituent code and repeats steps S617 to S627 until current column constituent code, to which the decoding operation is performed, is the last column constituent code corresponding to the predetermined number (C_max) of the column constituent codes.

When the j-th column constituent code is the last column constituent code corresponding to the predetermined number (C_max) of the column constituent codes as the determination result of step S627 (“YES”), the controller 120 may perform step S631 for determining whether l-th total decoding operation is successful.

When the l-th total decoding operation is successful as the determination result of step S631 (“YES”), the controller 120 may obtain the total number (ê) of error-corrected bits by adding the backup number (e_{r,i}^{˜}) of error-corrected bits in the i-th row constituent code and the backup number (e_{c,j}^{˜}) of error-corrected bits in the j-th column constituent code, which are obtained up to the l-th total decoding operation, at step S637. The total number (ê) of error-corrected bits may be expressed as:

ê=Σᵢ(e_{r,i}^{˜})+Σⱼ(e_{c,j}^{˜}) (21)

The controller 120 may obtain the total number (ê) of error-corrected bits by adding the backup number (e_{r,i}^{˜}) of error-corrected bits in the i-th row constituent code and the backup number (e_{c,j}^{˜}) of error-corrected bits in the j-th column constituent code, which are obtained up to the l-th total decoding operation, without performing remaining total decoding operation among the total decoding operations of the total number (I_max).

Further, the controller 120 transmits the total number (ê) of error-corrected bits up to the l-th total decoding operation and the success flag to the host 100 at step S639.

When the l-th total decoding operation is not successful as the determination result of step S631 (“NO”), the controller 120 may determine whether the number of total decoding operations up to the l-th total decoding operation is the same as the total number (I_max) of the total decoding operations at step S633.

When the number of total decoding operations up to the l-th total decoding operation is the same as the total number (I_max) of the total decoding operations as the determination result of step S633, the total number (I_max) of the total decoding operations is completed without success and thus the controller 120 may obtain the total number (ê) of error-corrected bits by adding the backup number (e_{r,i}^{˜}) of error-corrected bits in the i-th row constituent code and the backup number (e_{c,j}^{˜}) of error-corrected bits in the j-th column constituent code, which are obtained up to the total number (I_max) of the total decoding operations. The total number (ê) of error-corrected bits up to the total number (I_max) of the total decoding operations may be expressed as per equation 21 of step S637.

Further, the controller 120 may transmit the total number (ê) of error-corrected bits up to the total number (I_max) of the total decoding operations and a fail flag to the host 100 at step S643.

When the number of total decoding operations up to the l-th total decoding operation is not the same as the total number (I_max) of the total decoding operations as the determination result of step S633, the controller 120 increases the index of the total decoding operation (“l++”) at step S635 for the next total decoding operation and repeats steps S603 to S633 until the number of total decoding operations up to the current total decoding operation is the same as the total number (I_max) of the total decoding operations.

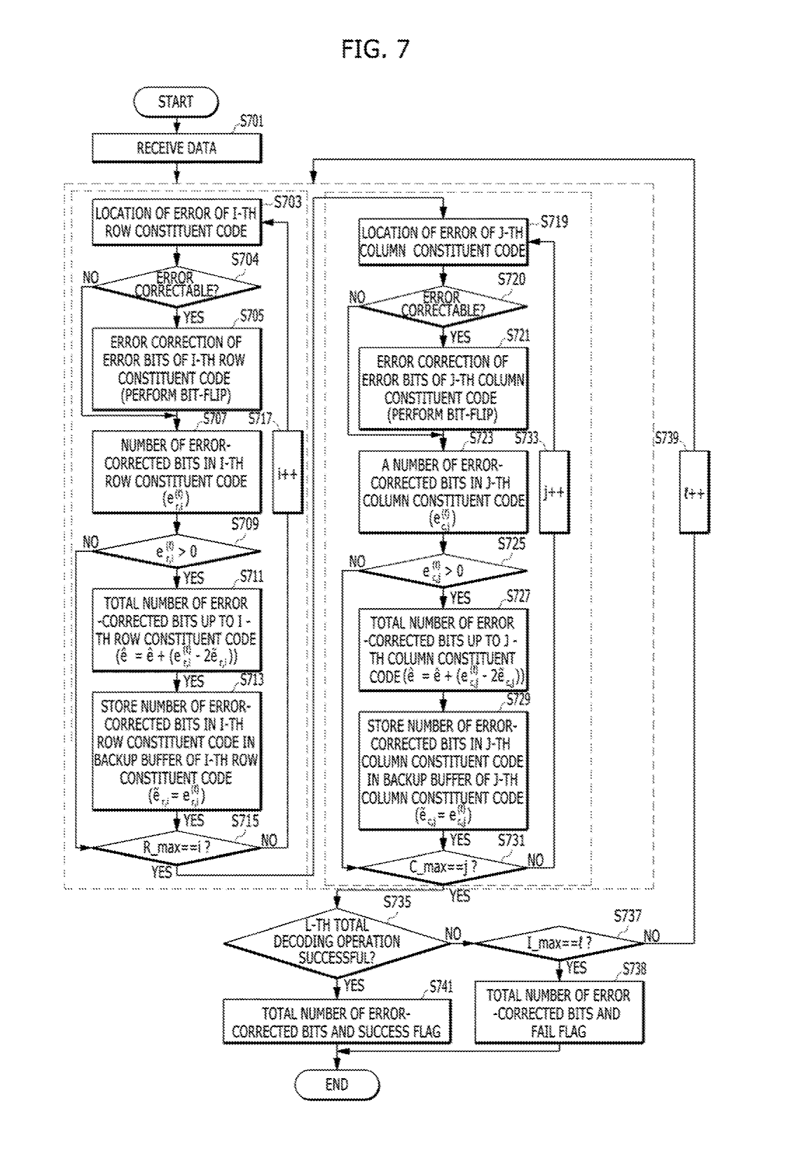

FIG. 7 is a flowchart illustrating an operation of a flash memory system according to a fourth embodiment. The operation may be performed by controller 120 of FIG. 1. The fourth embodiment may be applicable to a case where a bit of not the error location but the non-error location can be bit-flipped during the obtaining of the error location of the data.

The flow of FIG. 7 shows as an example the operation of obtaining a total number (ê) of error-corrected bits for data during the decoding operation to the data.

The data comprises the block-wise concatenated BCH code. The block-wise concatenated BCH code comprises two kinds of constituent codes, which are referred to as a row constituent code and a column constituent code, respectively.

The decoding operation to the data may be performed by firstly setting total number (I_max) of the total decoding operations, and then sequentially performing the l-th total decoding operation as many times as the total number (I_max) of the total decoding operations. Further, during each decoding operation of the total number (I_max) of the total decoding operations, a predetermined decoding operation to the row constituent code and a predetermined decoding operation to the column constituent code may be performed. According to the fourth embodiment, the decoding operation may be performed first to the row constituent code and then to the column constituent code. However, alternatively, the decoding operation may be performed first to the column constituent code and then to the decoding operation to the row constituent code.

The predetermined decoding operation to the row constituent code may be performed as many times as a predetermined number (R_max) of the row constituent codes of the data. The predetermined decoding operation to the column constituent code may be performed as many times as a predetermined number (C_max) of the column constituent code of the data.

The operation of obtaining the total number (ê) of error-corrected bits according to the fourth embodiment may be expressed as:

ê=Σₗ₌₀{Σᵢ(e_{r,i}^{(l)}−2e_{r,i}^{˜(l)})1_{r,i}^{(l)}+Σᵢ(e_{c,j}^{(l)}−2e_{c,j}^{˜(l)})1_{c,j}^{(l)}} (22)

Referring to FIG. 7, steps S701 to S707 for obtaining the number (e_{r,i(l)}) of error-corrected bits in the i-th row constituent code are the same as steps S401 to S407 described with reference to FIG. 4 and thus description for steps S701 to S707 is omitted.

At step S709, the controller 120 may determine whether the number (e_{r,i(l)}) of error-corrected bits in the i-th row constituent code obtained through steps S703 to S707 is greater than or equal to one (1_{r,i}^{(l)}) or whether there are one or more error-corrected bits through steps S703 to S707 (“e_{r,i}^{(l)}>0”).

When the number (e_{r,i}^{(l)}) of error-corrected bits in the l-th row constituent code obtained through steps S703 to S707 is not greater than or equal to one (1_{r,i}^{(l)}) as the determination result of step S709 (“NO”), step S715 may be performed.

When the number (e_{r,i}^{(l)}) of error-corrected bits in the i-th row constituent code obtained through steps S703 to S707 is greater than or equal to one (1_{r,i}^{(l)}) as the determination result of step S709 (“YES”), the controller 120 may obtain and may store the total number (ê) of error-corrected bits to the i-th row constituent code in a buffer at step S711. The total number (ê) of error-corrected bits up to the i-th row constituent code may be expressed as:

ê=ê+(e_{r,i}^{(l)}−2e_{r,i}^{˜}) (23)

In equation 23, e_{r,i}^{˜} denotes the number of error-corrected bits in the i-th row constituent code obtained through the decoding operation to the i-th row constituent code during the (l−1)th total decoding operation. An initial value of the number (e_{r,i}^{˜}) of error-corrected bits in the i-th row constituent code is zero (‘0’). Hereinafter, for the convenience of the description, the number (e_{r,i}^{˜}) of error-corrected bits in the i-th row constituent code is referred to as backup number (e_{r,i}^{˜}) of error-corrected bits in the i-th row constituent code. The backup number (e_{r,i}^{˜}) of error-corrected bits in the i-th row constituent code may be stored in a backup buffer of the i-th row constituent code.

The total number (ê) of error-corrected bits up to the i-th row constituent code during the l-th total decoding operation may be obtained by subtracting double of the backup number (e_{r,i}^{˜}) of error-corrected bits in the i-th row constituent code from the number (e_{r,i}^{(l)}) of error-corrected bits in the i-th row constituent code and then adding the subtraction result to the total number (ê) stored in the buffer, which is the total number (ê) of error-corrected bits up to the (i−1)th row constituent code.

The reason of doubling the backup number (e_{r,i}^{˜}) of error-corrected bits in the i-th row constituent code is because, when a non-error bit of the i-th row constituent code is erroneously error-corrected during the decoding operation to the i-th row constituent code of (l−1)th total decoding operation, the error-correction operation to the non-error bit erroneously error-corrected in the i-th row constituent code may be performed in order to recover the erroneously error-corrected bit during the decoding operation to a predetermined column constituent code of the (l−1)th total decoding operation. Therefore, such erroneous error-correction of the non-error bit is reflected to the total number (ê) of error-corrected bits and the erroneous error-correction of the non-error bit may affect the process of obtaining the total number (ê) of error-corrected bits and thus may make it hard to estimate the channel condition of the non-volatile memory device 200.

At step S713, the controller 120 may store the number (e_{r,i}^{(l)}) of error-corrected bits in the i-th row constituent code obtained at step S707 in the backup buffer of the i-th row constituent code as the backup number (e_{r,i}^{˜}) of error-corrected bits in the i-th row constituent code for performing step S711 through the decoding operation to the i-th row constituent code during (l+1)th total decoding operation.

The backup buffer of the i-th row constituent code is one of the same number of backup buffers as the number of row constituent codes.

At step S715, the controller 120 may determine whether the i-th row constituent code, to which the decoding operation may be performed, is the last row constituent code corresponding to the predetermined number (R_max) of the row constituent codes.

When the i-th row constituent code, to which the decoding operation may be performed, is not the last row constituent code corresponding to the predetermined number (R_max) of the row constituent codes as the determination result of step S715 (“NO”), the controller 120 increases the index of the row constituent code (“i++”) at step S717 for the decoding operation to (i+1)th row constituent code and repeats steps S703 to S715 until current row constituent code, to which the decoding operation may be performed, is the last row constituent code corresponding to the predetermined number (R_max) of the row constituent codes.

When the i-th row constituent code, to which the decoding operation may be performed, is the last row constituent code corresponding to the predetermined number (R_max) of the row constituent codes as the determination result of step S715 (“YES”), the controller 120 may perform step S719 for the decoding operation to the column constituent code.

Steps S719 to S723 for obtaining the number (e_{c,j}^{(l)}) of error-corrected bits in the j-th column constituent code are the same as steps S417 to S421 described with reference to FIG. 4 and thus description for steps S719 to S723 is omitted.

At step S725, the controller 120 may determine whether the number (e_{c,j}^{(l)}) of error-corrected bits in the j-th column constituent code obtained through steps S717 to S721 is greater than or equal to one (1_{c,j}^{(l)}) or whether there are one or more error-corrected bits through steps S717 to S721 (“e_{c,j}^{(l)}>0”).

When the number (e_{c,j}^{(l)}) of error-corrected bits in the j-th column constituent code obtained through steps S717 to S721 is not greater than or equal to one (1_{c,j}^{(l)}) as the determination result of step S725 (“NO”), step S731 may be performed.

When the number (e_{c,j}^{(l)}) of error-corrected bits in the j-th column constituent code obtained through steps S717 to S721 is greater than or equal to one (1_{c,j}^{(l)}) as the determination result of step S725 (“YES”), the controller 120 may obtain and may store the total number (ê) of error-corrected bits to the j-th column constituent code in the buffer at step S727. The total number (ê) of error-corrected bits up to the j-th column constituent code may be expressed as equation 24.

ê=ê+(e_{c,j}^{(l)}−2e_{c,j}^{˜}) (24)

In equation 24, e_{c,j}^{˜} denotes the number of error-corrected bits in the j-th column constituent code obtained through the decoding operation to the j-th column constituent code during the (l−1)th total decoding operation. An initial value of the number (e_{c,j}^{˜}) of error-corrected bits in the j-th column constituent code is zero (‘0’). Hereinafter, for the convenience of the description, the number (e_{c,j}^{˜}) of error-corrected bits in the j-th column constituent code is referred to as backup number (e_{c,j}^{˜}) of error-corrected bits in the j-th column constituent code. The backup number (e_{c,j}^{˜}) of error-corrected bits in the j-th column constituent code may be stored in a backup buffer of the j-th column constituent code.

The total number (ê) of error-corrected bits up to the j-th column constituent code during the l-th total decoding operation may be obtained by subtracting double of the backup number (e_{c,j}^{˜}) of error-corrected bits in the j-th column constituent code from the number (e_{c,j}^{(l)}) of error-corrected bits in the j-th column constituent code and then adding the subtraction result to the total number (ê) stored in the buffer, which is the total number (ê) of error-corrected bits up to the (j−1)th column constituent code.

The reason of doubling the backup number (e_{c,j}^{˜}) of error-corrected bits in the j-th column constituent code is because, when a non-error bit of the j-th column constituent code is erroneously error-corrected during the decoding operation to the j-th column constituent code of (l−1)th total decoding operation, the error-correction operation to the non-error bit erroneously error-corrected in the j-th column constituent code may be performed in order to recover the erroneously error-corrected bit during the decoding operation to a predetermined row constituent code of the (l−1)th total decoding operation. Therefore, such erroneous error-correction of the non-error bit is reflected to the total number (ê) of error-corrected bits and the erroneous error-correction of the non-error bit may affect the process of obtaining the total number (ê) of error-corrected bits and thus may make it hard to estimate the channel condition of the non-volatile memory device 200.

At step S729, the controller 120 may store the number (e_{c,j}^{(l)}) of error-corrected bits in the j-th column constituent code obtained at step S723 in the backup buffer of the j-th column constituent code as the backup number (e_{c,j}^{˜}) of error-corrected bits in the j-th column constituent code for performing step S727 through the decoding operation to the j-th column constituent code during (l+1)th total decoding operation.

The backup buffer of the j-th column constituent code is one of the same number of backup buffers as the number of column constituent codes.

At step S731, the controller 120 may determine whether the j-th column constituent code, to which the decoding operation may be performed, is the last column constituent code corresponding to the predetermined number (C_max) of the column constituent codes.

When the j-th column constituent code, to which the decoding operation may be performed, is not the last column constituent code corresponding to the predetermined number (C_max) of the column constituent codes as the determination result of step S731 (“NO”), the controller 120 increases the index of the column constituent code (“j++”) at step S739 for the decoding operation to (j+1)th column constituent code and repeats steps S719 to S731 until current column constituent code, to which the decoding operation may be performed, is the last column constituent code corresponding to the predetermined number (C_max) of the column constituent codes.

When the j-th column constituent code, to which the decoding operation may be performed, is the last column constituent code corresponding to the predetermined number (C_max) of the column constituent codes as the determination result of step S731 (“YES”), the controller 120 may perform step S735 for determining whether the l-th total decoding operation is successful.

When the l-th total decoding operation is successful as the determination result of step S735 (“YES”), the controller 120 transmits the total number (ê) of error-corrected bits up to the l-th total decoding operation and the success flag to the host 100 without performing remaining total decoding operation among the total decoding operations of the total number (I_max) at step S741. It is possible to estimate total number of error-corrected bits of the data through the total number (ê) of error-corrected bits up to the l-th total decoding operation, and thus to estimate the channel condition of the non-volatile memory device 200.

When the l-th total decoding operation is not successful as the determination result of step S735 (“NO”), the controller 120 may determine whether the number of total decoding operations up to the l-th total decoding operation is the same as the total number (I_max) of the total decoding operations at step S737.

When the number of total decoding operations up to the l-th total decoding operation is the same as the total number (I_max) of the total decoding operations as the determination result of step S737, the total number (I_max) of the total decoding operations is completed without success and thus the controller 120 transmits the total number (ê) of error-corrected bits up to the total number (I_max) of the total decoding operations and the fail flag to the host 100 at step S738.

When the number of total decoding operations up to the l-th total decoding operation is not the same as the total number (I_max) of the total decoding operations as the determination result of step S737, the controller 120 increases the index of the total decoding operation (“l++”) at step S739 for the next total decoding operation and repeats steps S703 to S737 until the number of total decoding operations up to the current total decoding operation is the same as the total number (I_max) of the total decoding operations.

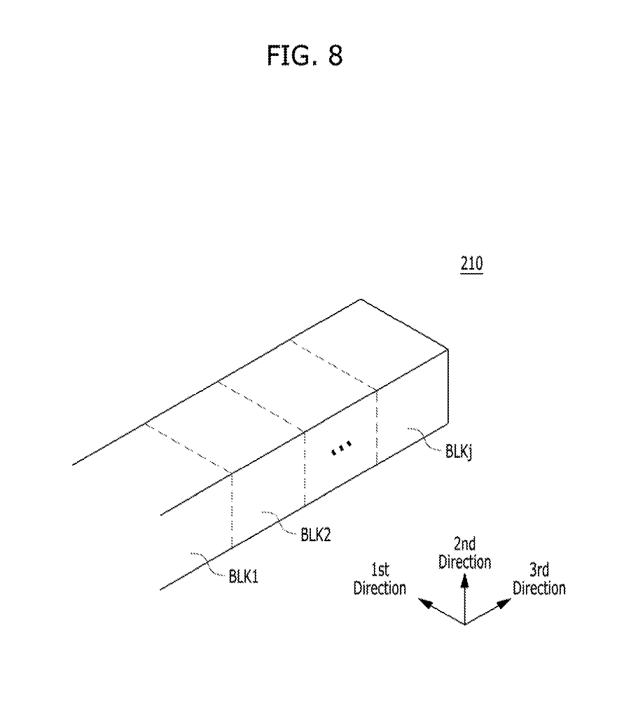

FIGS. 8 to 15 are schematic diagrams illustrating the memory device 150 shown in FIG. 1.

FIG. 8 is a block diagram illustrating an example of the memory blocks 210 of the memory device 200 shown in FIG. 1.

Referring to FIG. 8, the memory blocks 210 of the memory device 200 may include a plurality of memory blocks BLK1 to BLKj. Each of the memory blocks BLK1 to BLKj may have a three-dimensional (3D) structure or a vertical structure. For example, each of the memory blocks BLK1 to BLKj may include structures which extend in first to third directions, for example, an x-axis direction, a y-axis direction and a z-axis direction.

Each of the memory blocks BLK1 to BLKj may include a plurality of NAND strings NS which extend in the second direction. The plurality of NAND strings NS may be provided in the first direction and the third direction.

The respective NAND strings NS may be electrically coupled to a bit line BL, at least one source select line SSL, at least one ground select line GSL, a plurality of word lines WL, at least one dummy word lines DWL, and a common source line CSL. Namely, the respective memory blocks BLK1 to BLKj may be electrically coupled to a plurality of bit lines BL, a plurality of string select lines SSL, a plurality of ground select lines GSL, a plurality of word lines WL, a plurality of dummy word lines DWL, and a plurality of common source lines CSL.

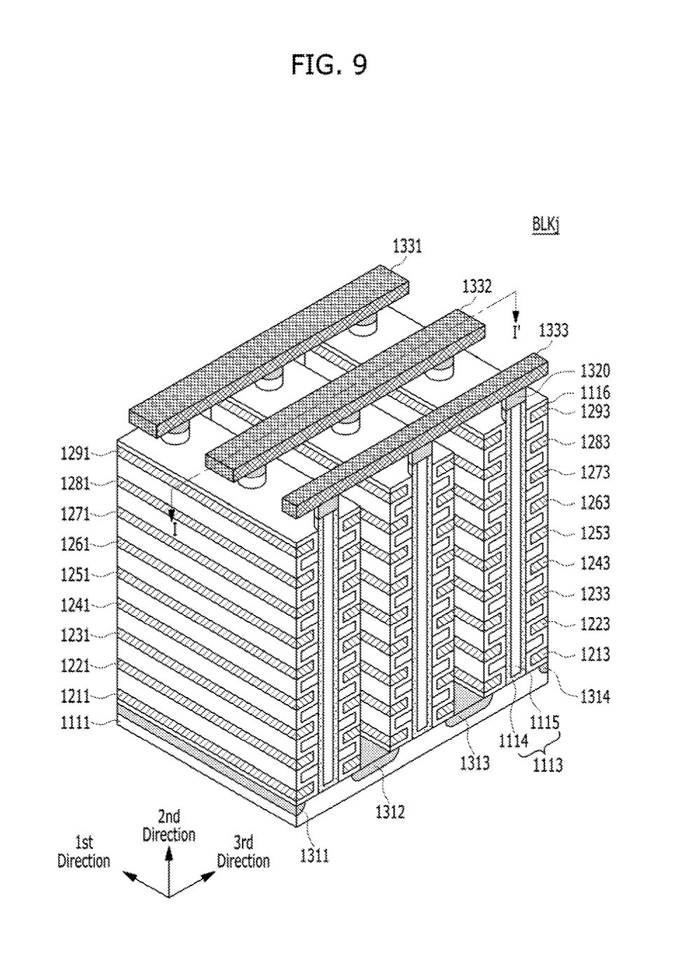

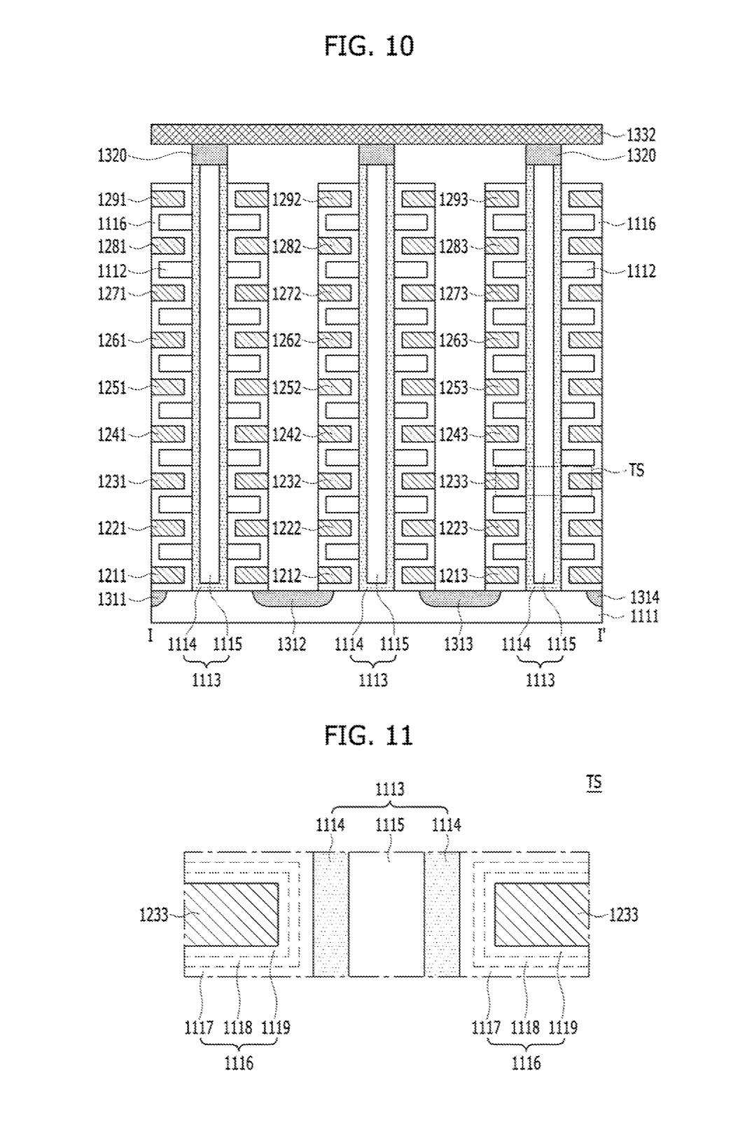

FIG. 9 is a perspective view of one memory block BLKj of the memory blocks BLK1 to BLKj shown in FIG. 8. FIG. 10 is a cross-sectional view taken along a line I-I′ of the memory block BLKj shown in FIG. 9.

Referring to FIGS. 9 and 10, a memory block BLKj among the plurality of memory blocks 210 of the memory device 200 may include a structure which extends in the first to third directions.

A substrate 1111 may be provided. The substrate 1111 may include a silicon material doped by a first type impurity. The substrate 1111 may include a silicon material doped by a p-type impurity or may be a p-type well, for example, a pocket p-well, and include an n-type well which surrounds the p-type well. While it is assumed that the substrate 1111 is p-type silicon, it is to be noted that the substrate 1111 is not limited to p-type silicon.

A plurality of doping regions 1311 to 1314 which extend in the first direction may be provided over the substrate 1111. The plurality of doping regions 1311 to 1314 may contain a second type of impurity that is different from the substrate 1111. The plurality of doping regions 1311 to 1314 may be doped with an n-type impurity. While it is assumed here that first to fourth doping regions 1311 to 1314 are n-type, it is to be noted that the first to fourth doping regions 1311 to 1314 are not limited to being n-type.

In the region over the substrate 1111 between the first and second doping regions 1311 and 1312, a plurality of insulation materials 1112 which extend in the first direction may be sequentially provided in the second direction. The insulation materials 1112 and the substrate 1111 may be separated from one another by a predetermined distance in the second direction. The dielectric materials 1112 may be separated from one another by a predetermined distance in the second direction. The dielectric materials 1112 may include a dielectric material such as silicon oxide.

In the region over the substrate 1111 between the first and second doping regions 1311 and 1312, a plurality of pillars 1113 which are sequentially disposed in the first direction and pass through the dielectric materials 1112 in the second direction may be provided. The plurality of pillars 1113 may respectively pass through the dielectric materials 1112 and may be electrically coupled with the substrate 1111. Each pillar 1113 may be configured by a plurality of materials. The surface layer 1114 of each pillar 1113 may include a silicon material doped with the first type of impurity. The surface layer 1114 of each pillar 1113 may include a silicon material doped with the same type of impurity as the substrate 1111. While it is assumed here that the surface layer 1114 of each pillar 1113 may include p-type silicon, the surface layer 1114 of each pillar 1113 is not limited to being p-type silicon.

An inner layer 1115 of each of the pillars 1113 may be formed of a dielectric material. The inner layer 1115 of each pillar 1113 may be filled by a dielectric material such as silicon oxide.

In the region between the first and second doping regions 1311 and 1312, a dielectric layer 1116 may be provided along the exposed surfaces of the dielectric materials 1112, the pillars 1113, and the substrate 1111. The thickness of the dielectric layer 1116 may be less than half of the distance between the dielectric materials 1112. For example, a region, in which a material other than the dielectric materials 1112 and the dielectric layer 1116 may be disposed, may be provided between (i) the dielectric layer 1116 provided over the bottom surface of a first dielectric material of the dielectric materials 1112 and (ii) the dielectric layer 1116 provided over the top surface of a second dielectric material of the dielectric materials 1112. The dielectric materials 1112 lie below the first dielectric material.

In the region between the first and second doping regions 1311 and 1312, conductive materials 1211 to 1291 may be provided over the exposed of the dielectric layer 1116. The conductive material 1211 which extends in the first direction may be provided between the dielectric material 1112 adjacent to the substrate 1111 and the substrate 5111. In particular, the conductive material 1211 which extends in the first direction may be provided between (i) the dielectric layer 1116 disposed over the substrate 1111 and (ii) the dielectric layer 1116 disposed over the bottom surface of the dielectric material 1112 adjacent to the substrate 1111.

The conductive material which extends in the first direction may be provided between (i) the dielectric layer 1116 disposed over the top surface of one of the dielectric materials 1112 and (ii) the dielectric layer 1116 disposed over the bottom surface of another dielectric material of the dielectric materials 1112, which is disposed over the certain dielectric material 1112. The conductive materials 1221 to 1281 which extend in the first direction may be provided between the dielectric materials 1112. The conductive material 1291 which extends in the first direction may be provided over the uppermost dielectric material 1112. The conductive materials 1211 to 1291 which extend in the first direction may be a metallic material. The conductive materials 1211 to 1291 which extend in the first direction may be a conductive material such as polysilicon.

In the region between the second and third doping regions 1312 and 1313, the same structures as the structures between the first and second doping regions 1311 and 1312 may be provided. For example, in the region between the second and third doping regions 1312 and 1313, the plurality of Insulation materials 1112 which extend in the first direction, the plurality of pillars 1113 which are sequentially arranged in the first direction and pass through the plurality of dielectric materials 1112 in the second direction, the dielectric layer 1116 which is provided over the exposed surfaces of the plurality of dielectric materials 1112 and the plurality of pillars 1113, and the plurality of conductive materials 1212 to 1292 which extend in the first direction may be provided.

In the region between the third and fourth doping regions 1313 and 1314, the same structure as between the first and second doping regions 1311 and 1312 may be provided. For example, in the region between the third and fourth doping regions 1313 and 1314, the plurality of dielectric materials 1112 which extend in the first direction, the plurality of pillars 1113 which are sequentially arranged in the first direction and pass through the plurality of dielectric materials 1112 in the second direction, the dielectric layer 1116 which is provided over the exposed surfaces of the plurality of dielectric materials 1112 and the plurality of pillars 1113, and the plurality of conductive materials 1213 to 1293 which extend in the first direction may be provided.

Drains 1320 may be respectively provided over the plurality of pillars 1113. The drains 1320 may be silicon materials doped with second type impurities. The drains 1320 may be silicon materials doped with n-type impurities. While it is assumed for the sake of convenience that the drains 1320 include n-type silicon, it is to be noted that the drains 1320 are not limited to being n-type silicon. For example, the width of each drain 1320 may be larger than the width of each corresponding pillars 1113. Each drain 1320 may be provided in the shape of a pad over the top surface of each corresponding pillar 1113.

Conductive materials 1331 to 1333 which extend in the third direction may be provided over the drains 1320. The conductive materials 1331 to 1333 may be sequentially disposed in the first direction. The respective conductive materials 1331 to 1333 may be electrically coupled with the drains 1320 of corresponding regions. The drains 1320 and the conductive materials 1331 to 1333 which extend in the third direction may be electrically coupled with through contact plugs. The conductive materials 1331 to 1333 which extend in the third direction may be a metallic material. The conductive materials 1331 to 1333 which extend in the third direction may be a conductive material such as polysilicon.

Referring to FIGS. 9 and 10, the respective pillars 1113 may form strings together with the dielectric layer 1116 and the conductive materials 1211 to 1291, 1212 to 1292 and 1213 to 1293 which extend in the first direction. The respective pillars 1113 may form NAND strings NS together with the dielectric layer 1116 and the conductive materials 1211 to 1291, 1212 to 1292, and 1213 to 1293 which extend in the first direction. Each NAND string NS may include a plurality of transistor structures TS.

FIG. 11 is a cross-sectional view of the transistor structure TS shown in FIG. 10.

Referring to FIG. 11, in the transistor structure TS shown in FIG. 10, the dielectric layer 1116 may include first to third sub dielectric layers 1117, 1118 and 1119.

The surface layer 1114 of p-type silicon in each of the pillars 1113 may serve as a body. The first sub dielectric layer 1117 adjacent to the pillar 1113 may serve as a tunneling dielectric layer, and may include a thermal oxidation layer.

The second sub dielectric layer 1118 may serve as a charge storing layer. The second sub dielectric layer 1118 may serve as a charge capturing layer, and may include a nitride layer or a metal oxide layer such as an aluminum oxide layer, a hafnium oxide layer, or the like.

The third sub dielectric layer 1119 adjacent to the conductive material 1233 may serve as a blocking dielectric layer. The third sub dielectric layer 1119 adjacent to the conductive material 1233 which extends in the first direction may be formed as a single layer or multiple layers. The third sub dielectric layer 1119 may be a high-k dielectric layer such as an aluminum oxide layer, a hafnium oxide layer, or the like, which has a dielectric constant greater than the first and second sub dielectric layers 1117 and 1118.

The conductive material 1233 may serve as a gate or a control gate. That is, the gate or the control gate 1233, the blocking dielectric layer 1119, the charge storing layer 1118, the tunneling dielectric layer 1117 and the body 1114 may form a transistor or a memory cell transistor structure. For example, the first to third sub dielectric layers 1117 to 1119 may form an oxide-nitride-oxide (ONO) structure. In the embodiment, for the sake of convenience, the surface layer 1114 of p-type silicon in each of the pillars 1113 will be referred to as a body in the second direction.

The memory block BLKj may include the plurality of pillars 1113. Namely, the memory block BLKj may include the plurality of NAND strings NS. In detail, the memory block BLKj may include the plurality of NAND strings NS which extend in the second direction or a direction perpendicular to the substrate 1111.

Each NAND string NS may include the plurality of transistor structures TS which are disposed in the second direction. At least one of the plurality of transistor structures TS of each NAND string NS may serve as a string source transistor SST. At least one of the plurality of transistor structures TS of each NAND string NS may serve as a ground select transistor GST.

The gates or control gates may correspond to the conductive materials 1211 to 1291, 1212 to 1292 and 1213 to 1293 which extend in the first direction. For example, the gates or the control gates may extend in the first direction and form word lines and at least two select lines, at least one source select line SSL and at least one ground select line GSL.

The conductive materials 1331 to 1333 which extend in the third direction may be electrically coupled to one end of the NAND strings NS. The conductive materials 1331 to 1333 which extend in the third direction may serve as bit lines BL. That is, in one memory block BLKi, the plurality of NAND strings NS may be electrically coupled to one bit line BL.

The second type doping regions 1311 to 1314 which extend in the first direction may be provided to the other ends of the NAND strings NS. The second type doping regions 1311 to 1314 which extend in the first direction may serve as common source lines CSL.

Namely, the memory block BLKi may include a plurality of NAND strings NS which extend in a direction perpendicular to the substrate 1111, e.g., the second direction, and may serve as a NAND flash memory block, for example, of a charge capturing type memory, in which a plurality of NAND strings NS are electrically coupled to one bit line BL.

While it is illustrated in FIGS. 9 to 11 that the conductive materials 1211 to 1291, 1212 to 1292 and 1213 to 1293 which extend in the first direction are provided in 9 layers, it is to be noted that the conductive materials 1211 to 1291, 1212 to 1292 and 1213 to 1293 which extend in the first direction are not limited to being provided in 9 layers. For example, conductive materials which extend in the first direction may be provided in 8 layers, 16 layers or any multiple of layers. For example, in one NAND string NS, the number of transistors may be 8, 16 or more. While it is illustrated in FIGS. 9 to 11 that 3 NAND strings NS are electrically coupled to one bit line BL, it is to be noted that the embodiment is not limited to having 3 NAND strings NS that are electrically coupled to one bit line BL. In the memory block BLKj, m number of NAND strings NS may be electrically coupled to one bit line BL, m being a positive integer. According to the number of NAND strings NS which are electrically coupled to one bit line BL, the number of conductive materials 1211 to 1291, 1212 to 1292 and 1213 to 1293 which extend in the first direction and the number of common source lines 1311 to 1314 may be controlled as well.

Further, while it is illustrated in FIGS. 9 to 11 that 3 NAND strings NS are electrically coupled to one conductive material which extends in the first direction, it is to be noted that the embodiment is not limited to having 3 NAND strings NS electrically coupled to one conductive material which extends in the first direction. For example, n number of NAND strings NS may be electrically coupled to one conductive material which extends in the first direction, n being a positive integer. According to the number of NAND strings NS which are electrically coupled to one conductive material which extends in the first direction, the number of bit lines 1331 to 1333 may be controlled as well.

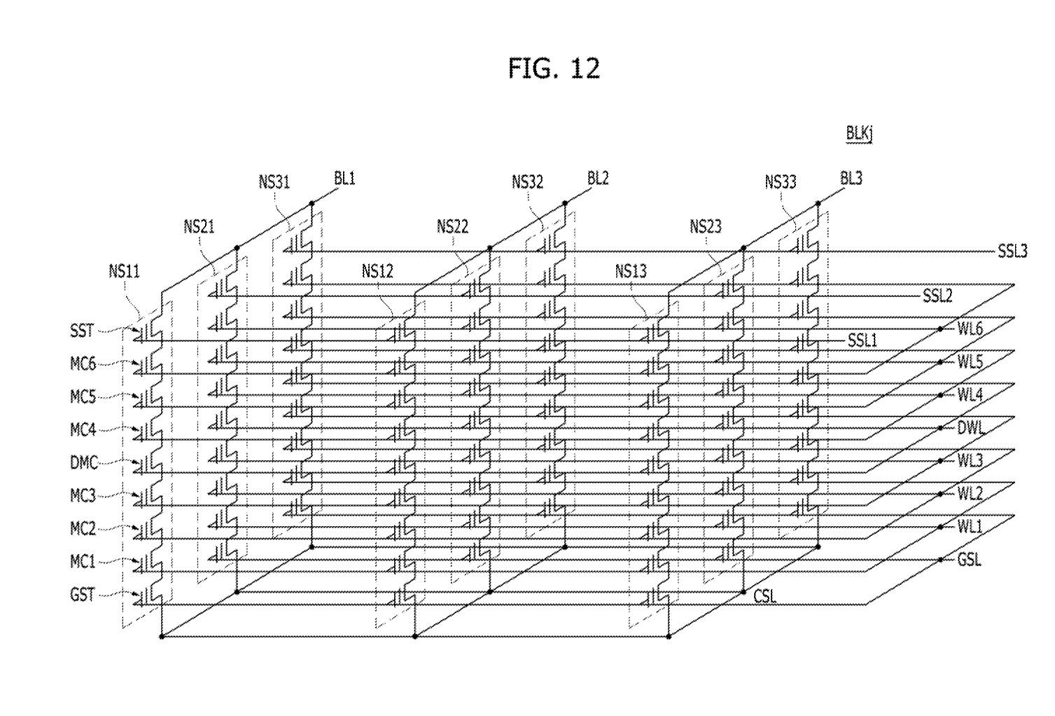

FIG. 12 is an equivalent circuit diagram Illustrating the memory block BLKj having a first structure described with reference to FIGS. 9 to 11.

Referring to FIG. 12, in a block BLKj having the first structure, NAND strings NS11 to NS31 may be provided between a first bit line BL1 and a common source line CSL. The first bit line BL1 may correspond to the conductive material 1331 of FIGS. 9 and 10, which extends in the third direction. NAND strings NS12 to NS32 may be provided between a second bit line BL2 and the common source line CSL. The second bit line BL2 may correspond to the conductive material 1332 of FIGS. 9 and 10, which extends in the third direction. NAND strings NS13 to NS33 may be provided between a third bit line BL3 and the common source line CSL. The third bit line BL3 may correspond to the conductive material 1333 of FIGS. 9 and 10, which extends in the third direction.

A source select transistor SST of each NAND string NS may be electrically coupled to a corresponding bit line BL. A ground select transistor GST of each NAND string NS may be electrically coupled to the common source line CSL. Memory cells MC may be provided between the source select transistor SST and the ground select transistor GST of each NAND string NS.

In this example, NAND strings NS may be defined by units of rows and columns and NAND strings NS which are electrically coupled to one bit line may form one column. The NAND strings NS11 to NS31 which are electrically coupled to the first bit line BL1 may correspond to a first column, the NAND strings NS12 to NS32 which are electrically coupled to the second bit line BL2 may correspond to a second column, and the NAND strings NS13 to NS33 which are electrically coupled to the third bit line BL3 may correspond to a third column. NAND strings NS which are electrically coupled to one source select line SSL may form one row. The NAND strings NS11 to NS13 which are electrically coupled to a first source select line SSL1 may form a first row, the NAND strings NS21 to NS23 which are electrically coupled to a second source select line SSL2 may form a second row, and the NAND strings NS31 to NS33 which are electrically coupled to a third source select line SSL3 may form a third row.

In each NAND string NS, a height may be defined. In each NAND string NS, the height of a memory cell MC1 adjacent to the ground select transistor GST may have a value ‘1’. In each NAND string NS, the height of a memory cell may increase as the memory cell gets closer to the source select transistor SST when measured from the substrate 1111. In each NAND string NS, the height of a memory cell MC6 adjacent to the source select transistor SST may be 7.

The source select transistors SST of the NAND strings NS in the same row may share the source select line SSL. The source select transistors SST of the NAND strings NS in different rows may be respectively electrically coupled to the different source select lines SSL1, SSL2 and SSL3.

The memory cells at the same height in the NAND strings NS in the same row may share a word line WL. That is, at the same height, the word lines WL electrically coupled to the memory cells MC of the NAND strings NS in different rows may be electrically coupled. Dummy memory cells DMC at the same height in the NAND strings NS of the same row may share a dummy word line DWL. Namely, at the same height or level, the dummy word lines DWL electrically coupled to the dummy memory cells DMC of the NAND strings NS in different rows may be electrically coupled.

The word lines WL or the dummy word lines DWL located at the same level or height or layer may be electrically coupled with one another at layers where the conductive materials 1211 to 1291, 1212 to 1292 and 1213 to 1293 which extend in the first direction may be provided. The conductive materials 1211 to 1291, 1212 to 1292 and 1213 to 1293 which extend in the first direction may be electrically coupled in common to upper layers through contacts. At the upper layers, the conductive materials 1211 to 1291, 1212 to 1292 and 1213 to 1293 which extend in the first direction may be electrically coupled. For example, the ground select transistors GST of the NAND strings NS in the same row may share the ground select line GSL. Further, the ground select transistors GST of the NAND strings NS in different rows may share the ground select line GSL. That is, the NAND strings NS11 to NS13, NS21 to NS23 and NS31 to NS33 may be electrically coupled to the ground select line GSL.

The common source line CSL may be electrically coupled to the NAND strings NS. Over the active regions and over the substrate 1111, the first to fourth doping regions 1311 to 1314 may be electrically coupled. The first to fourth doping regions 1311 to 1314 may be electrically coupled to an upper layer through contacts and, at the upper layer, the first to fourth doping regions 1311 to 1314 may be electrically coupled.

Namely, as shown in FIG. 12, the word lines WL of the same height or level may be electrically coupled. Accordingly, when a word line WL at a specific height is selected, all NAND strings NS which are electrically coupled to the word line WL may be selected. The NAND strings NS in different rows may be electrically coupled to different source select lines SSL. Accordingly, among the NAND strings NS electrically coupled to the same word line WL, by selecting one of the source select lines SSL1 to SSL3, the NAND strings NS in the unselected rows may be electrically isolated from the bit lines BL1 to BL3. For example, by selecting one of the source select lines SSL1 to SSL3, a row of NAND strings NS may be selected. Moreover, by selecting one of the bit lines BL1 to BL3, the NAND strings NS in the selected rows may be selected in units of columns.

In each NAND string NS, a dummy memory cell DMC may be provided. In FIG. 12, the dummy memory cell DMC may be provided between a third memory cell MC3 and a fourth memory cell MC4 in each NAND string NS. That is, first to third memory cells MC1 to MC3 may be provided between the dummy memory cell DMC and the ground select transistor GST. Fourth to sixth memory cells MC4 to MC6 may be provided between the dummy memory cell DMC and the source select transistor SST. The memory cells MC of each NAND string NS may be divided into memory cell groups by the dummy memory cell DMC. In the divided memory cell groups, memory cells, for example, MC1 to MC3, adjacent to the ground select transistor GST may be referred to as a lower memory cell group, and memory cells, for example, MC4 to MC6, adjacent to the string select transistor SST may be referred to as an upper memory cell group.

As described in FIGS. 8 to 12, a semiconductor memory system may include one or more cell strings arranged in a direction perpendicular to a substrate coupled with a memory controller and including memory cells, a string select transistor and a ground select transistor. The semiconductor memory system may operate as follow: (a) may be provided with a first read command to perform first and second hard decision read operations in response to a first hard decision read voltage and a second hard decision read voltage that is different from the first hard decision read voltage; (b) may acquire hard decision data; (c) may select one of the first and second hard decision voltages based on an error bit state of the hard decision data; (d) may acquire soft decision data in response to a soft read voltage that is different from the first and second hard decision read voltages; and (e) may provide the soft decision data to a memory controller.

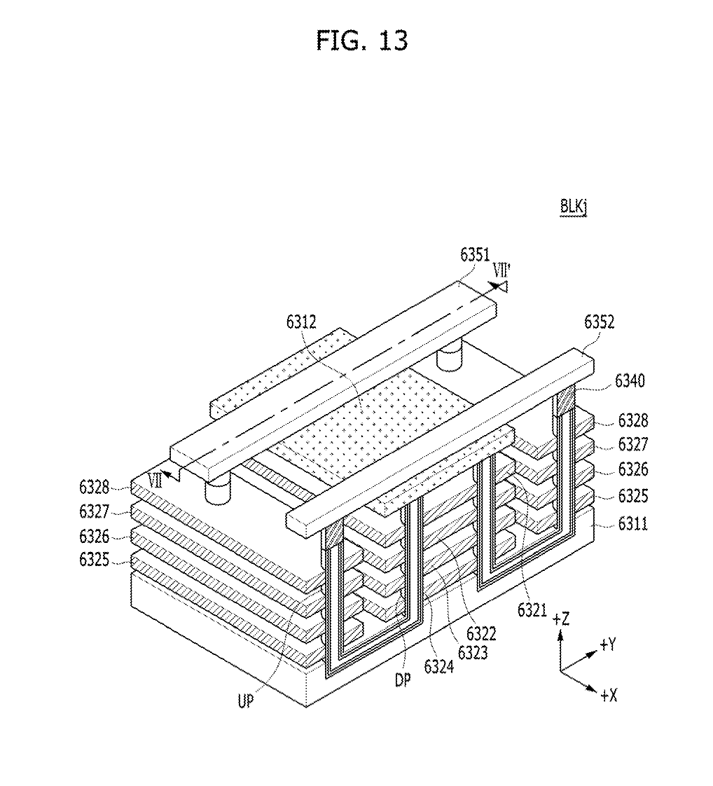

Hereinbelow, detailed descriptions will be made with reference to FIGS. 13 to 15, which show the memory device in the memory system according to an embodiment implemented with a three-dimensional (3D) nonvolatile memory device different from the first structure.

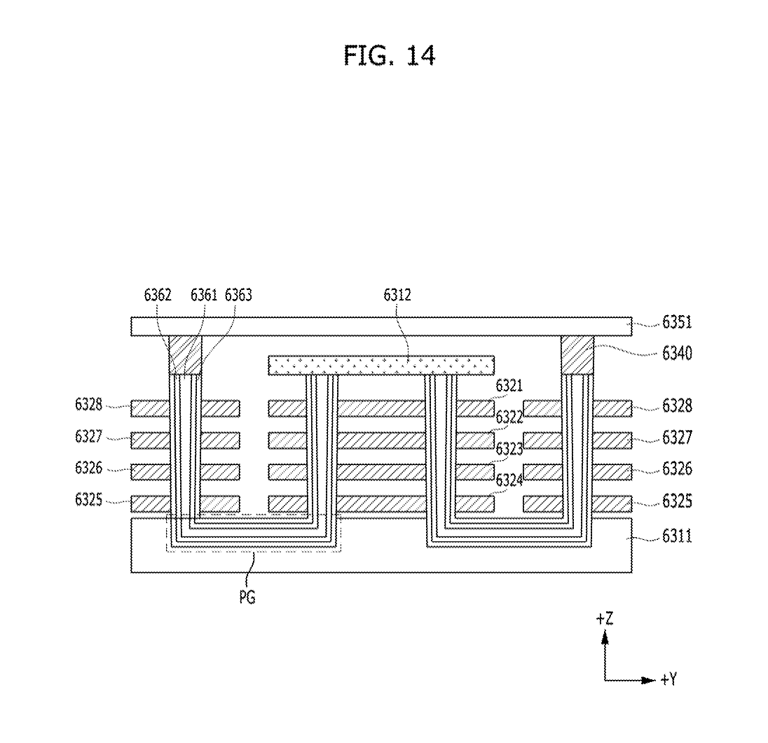

FIG. 13 is a perspective view schematically illustrating the memory device implemented with the three-dimensional (3D) nonvolatile memory device, which is different from the first structure described above with reference to FIGS. 9 to 12, and showing a memory block BLKj of the plurality of memory blocks of FIG. 8. FIG. 14 is a cross-sectional view illustrating the memory block BLKj taken along the line VII-VII′ of FIG. 13.

Referring to FIGS. 13 and 14, the memory block BLKj among the plurality of memory blocks of the memory device 200 of FIG. 1 may include structures which extend in the first to third directions.

A substrate 6311 may be provided. For example, the substrate 6311 may include a silicon material doped with a first type impurity. For example, the substrate 6311 may include a silicon material doped with a p-type impurity or may be a p-type well, for example, a pocket p-well, and include an n-type well which surrounds the p-type well. While it is assumed in the embodiment for the sake of convenience that the substrate 6311 is p-type silicon, it is to be noted that the substrate 6311 is not limited to being p-type silicon.

First to fourth conductive materials 6321 to 6324 which extend in the x-axis direction and the y-axis direction are provided over the substrate 6311. The first to fourth conductive materials 6321 to 6324 may be separated by a predetermined distance in the z-axis direction.

Fifth to eighth conductive materials 6325 to 6328 which extend in the x-axis direction and the y-axis direction may be provided over the substrate 6311. The fifth to eighth conductive materials 6325 to 6328 may be separated by the predetermined distance in the z-axis direction. The fifth to eighth conductive materials 6325 to 6328 may be separated from the first to fourth conductive materials 6321 to 6324 in the y-axis direction.

A plurality of lower pillars DP which pass through the first to fourth conductive materials 6321 to 6324 may be provided. Each lower pillar DP extends in the z-axis direction. Also, a plurality of upper pillars UP which pass through the fifth to eighth conductive materials 6325 to 6328 may be provided. Each upper pillar UP extends in the z-axis direction.

Each of the lower pillars DP and the upper pillars UP may include an internal material 6361, an intermediate layer 6362, and a surface layer 6363. The Intermediate layer 6362 may serve as a channel of the cell transistor. The surface layer 6363 may include a blocking dielectric layer, a charge storing layer and a tunneling dielectric layer.

The lower pillar DP and the upper pillar UP may be electrically coupled through a pipe gate PG. The pipe gate PG may be disposed in the substrate 6311. For instance, the pipe gate PG may include the same material as the lower pillar DP and the upper pillar UP.

A doping material 6312 of a second type which extends in the x-axis direction and the y-axis direction may be provided over the lower pillars DP. For example, the doping material 6312 of the second type may include an n-type silicon material. The doping material 6312 of the second type may serve as a common source line CSL.

Drains 6340 may be provided over the upper pillars UP. The drains 6340 may include an n-type silicon material. First and second upper conductive materials 6351 and 6352 which extend in the y-axis direction may be provided over the drains 6340.

The first and second upper conductive materials 6351 and 6352 may be separated in the x-axis direction. The first and second upper conductive materials 6351 and 6352 may be formed of a metal. The first and second upper conductive materials 6351 and 6352 and the drains 6340 may be electrically coupled through contact plugs. The first and second upper conductive materials 6351 and 6352 respectively serve as first and second bit lines BL1 and BL2.

The first conductive material 6321 may serve as a source select line SSL, the second conductive material 6322 may serve as a first dummy word line DWL1, and the third and fourth conductive materials 6323 and 6324 serve as first and second main word lines MWL1 and MWL2, respectively. The fifth and sixth conductive materials 6325 and 6326 serve as third and fourth main word lines MWL3 and MWL4, respectively, the seventh conductive material 6327 may serve as a second dummy word line DWL2, and the eighth conductive material 6328 may serve as a drain select line DSL.

The lower pillar DP and the first to fourth conductive materials 6321 to 6324 adjacent to the lower pillar DP form a lower string. The upper pillar UP and the fifth to eighth conductive materials 6325 to 6328 adjacent to the upper pillar UP form an upper string. The lower string and the upper string may be electrically coupled through the pipe gate PG. One end of the lower string may be electrically coupled to the doping material 6312 of the second type which serves as the common source line CSL. One end of the upper string may be electrically coupled to a corresponding bit line through the drain 6340. One lower string and one upper string form one cell string which is electrically coupled between the doping material 6312 of the second type serving as the common source line CSL and a corresponding one of the upper conductive material layers 6351 and 6352 serving as the bit line BL.

That is, the lower string may include a source select transistor SST, the first dummy memory cell DMC1, and the first and second main memory cells MMC1 and MMC2. The upper string may include the third and fourth main memory cells MMC3 and MMC4, the second dummy memory cell DMC2, and a drain select transistor DST.

In FIGS. 13 and 14, the upper string and the lower string may form a NAND string NS, and the NAND string NS may include a plurality of transistor structures TS. Since the transistor structure included in the NAND string NS in FIGS. 13 and 14 is described above in detail with reference to FIG. 11, a detailed description thereof will be omitted herein.

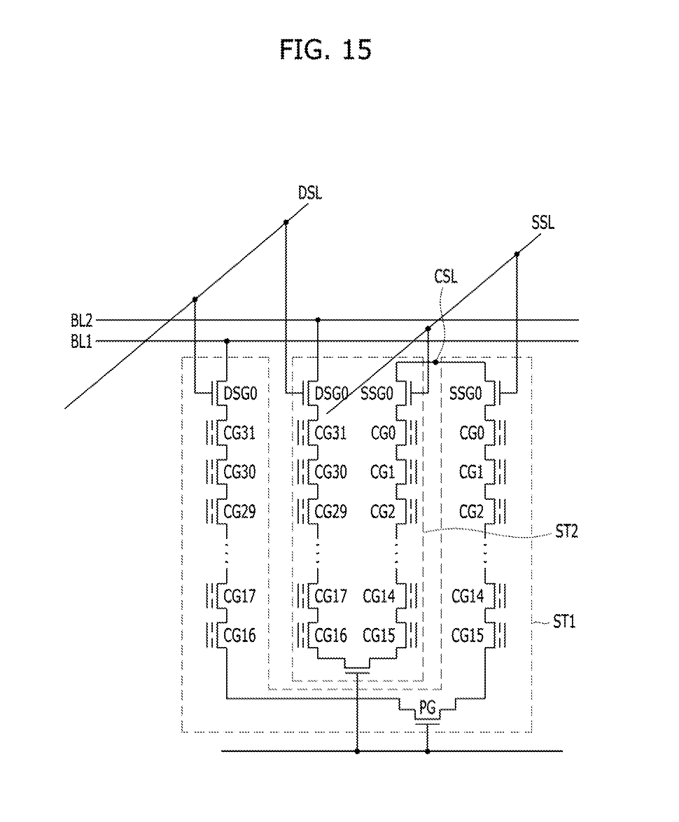

FIG. 15 is a circuit diagram illustrating the equivalent circuit of the memory block BLKj having the second structure as described above with reference to FIGS. 13 and 14. For the sake of convenience, only a first string and a second string, which form a pair in the memory block BLKj in the second structure are shown.

Referring to FIG. 15, in the memory block BLKj having the second structure among the plurality of blocks of the memory device 150, cell strings, each of which is implemented with one upper string and one lower string electrically coupled through the pipe gate PG as described above with reference to FIGS. 13 and 14, may be provided in such a way as to define a plurality of pairs.

Namely, in the certain memory block BLKj having the second structure, memory cells CG0 to CG31 stacked along a first channel CH1 (not shown), for example, at least one source select gate SSG1 and at least one drain select gate DSG1 may form a first string ST1, and memory cells CG0 to CG31 stacked along a second channel CH2 (not shown), for example, at least one source select gate SSG2 and at least one drain select gate DSG2 may form a second string ST2.

The first string ST1 and the second string ST2 may be electrically coupled to the same drain select line DSL and the same source select line SSL. The first string ST1 may be electrically coupled to a first bit line BL1, and the second string ST2 may be electrically coupled to a second bit line BL2.

While it is described in FIG. 15 that the first string ST1 and the second string ST2 are electrically coupled to the same drain select line DSL and the same source select line SSL, it may be envisaged that the first string ST1 and the second string ST2 may be electrically coupled to the same source select line SSL and the same bit line BL, the first string ST1 may be electrically coupled to a first drain select line DSL1 and the second string ST2 may be electrically coupled to a second drain select line DSL2. Further it may be envisaged that the first string ST1 and the second string ST2 may be electrically coupled to the same drain select line DSL and the same bit line BL, the first string ST1 may be electrically coupled to a first source select line SSL1 and the second string ST2 may be electrically coupled a second source select line SSL2.

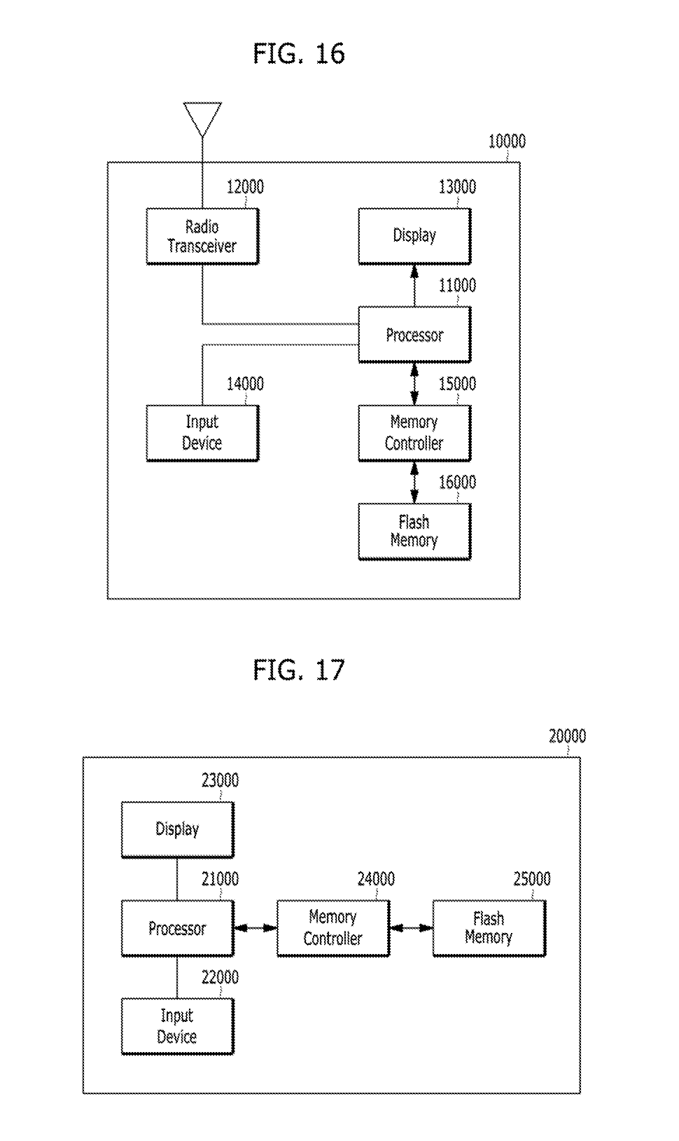

FIG. 16 is a block diagram schematically illustrating an electronic device 10000 including a memory controller 15000 and a flash memory 16000 according to an embodiment of the present invention.

Referring to FIG. 16, the electronic device 10000, which includes but is not limited to a cellular phone, a smart phone, or a tablet PC, may include the flash memory 16000 implemented by a flash memory device and the memory controller 15000 for controlling the flash memory 16000. The flash memory 16000 may correspond to the memory system 110 described above with reference to FIGS. 3 to 13. The flash memory 16000 may store random data. The memory controller 15000 may be controlled by a processor 11000 which controls overall operations of the electronic device 10000.

Data stored in the flash memory 16000 may be displayed through a display 13000 under the control of the memory controller 15000. The memory controller 15000 operates under the control of the processor 11000.

A radio transceiver 12000 may receive and output a radio signal through an antenna (ANT). For example, the radio transceiver 12000 may convert the radio signal received from the antenna into a signal which will be processed by the processor 11000. Thus, the processor 11000 may process the signal converted by the radio transceiver 12000, and may store the processed signal at the flash memory 16000. Otherwise, the processor 11000 may display the processed signal through the display 13000.

The radio transceiver 12000 may convert a signal from the processor 11000 into a radio signal, and may output the converted radio signal externally through the antenna.

An input device 14000 may receive a control signal for controlling an operation of the processor 11000 or data to be processed by the processor 11000, and may be implemented by a pointing device such as a touch pad, a computer mouse, a key pad, and a keyboard.

The processor 11000 may control the display 13000 such that data from the flash memory 16000, the radio signal from the radio transceiver 12000, or the data from the input device 14000 is displayed through the display 13000.

FIG. 17 is a block diagram schematically illustrating an electronic device 20000 including a memory controller 24000 and a flash memory 25000 according to an embodiment of the present invention.

Referring to FIG. 17, the electronic device 20000 may be implemented by a data processing device such as a personal computer (PC), a tablet computer, a net-book, an e-reader, a personal digital assistant (PDA), a portable multimedia player (PMP), an MP3 player, and an MP4 player, and may include the flash memory 25000, for example, the flash memory device, and the memory controller 24000 to control an operation of the flash memory 25000.

The electronic device 20000 may include a processor 21000 to control overall operations of the electronic device 20000. The memory controller 24000 may be controlled by the processor 21000.

The processor 21000 may display data stored in the semiconductor memory system through a display 23000 in response to an input signal from an input device 22000. For example, the Input device 22000 may be implemented by a pointing device such as a touch pad, a computer mouse, a key pad, and a keyboard.

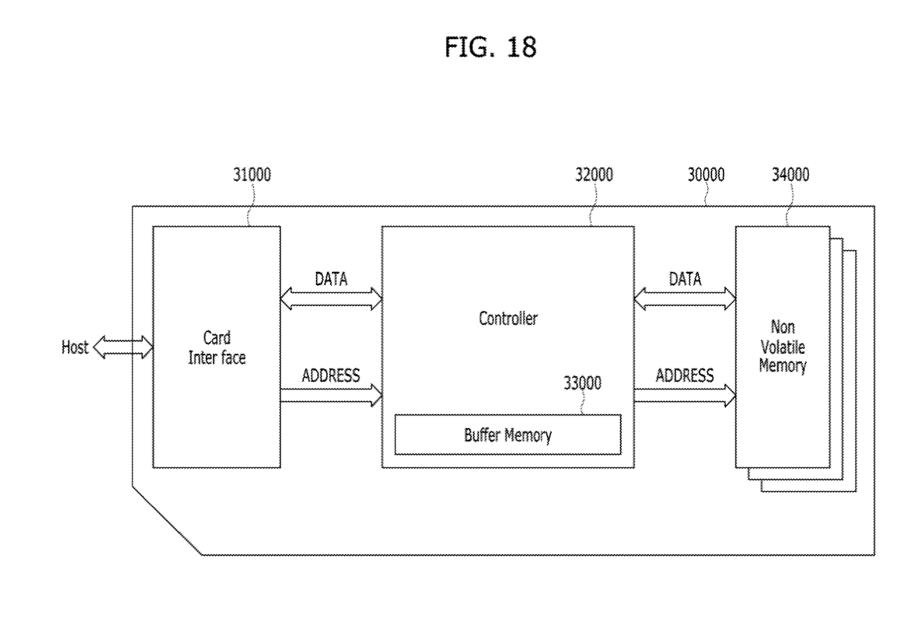

FIG. 18 is a block diagram schematically illustrating an electronic device 30000 including a controller 32000 and a non-volatile memory 34000 according to an embodiment of the present invention.

Referring to FIG. 18, the electronic device 30000 may include a card interface 31000, the controller 32000, and the non-volatile memory 34000, for example, a flash memory device.

The electronic device 30000 may exchange data with a host through the card interface 31000. The card interface 31000 may be a secure digital (SD) card interface or a multi-media card (MMC) interface, which does not limit the scope of the present invention. The card Interface 31000 may interface the host and the controller 32000 according to a communication protocol of the host that is capable of communicating with the electronic device 30000.

The controller 32000 may control overall operations of the electronic device 30000, and may control data exchange between the card Interface 31000 and the non-volatile memory 34000. A buffer memory 33000 of the controller 32000 may buffer data transferred between the card interface 31000 and the non-volatile memory 34000.

The controller 32000 may be coupled with the card interface 31000 and the non-volatile memory 34000 through a data bus DATA and an address bus ADDRESS. According to an embodiment, the controller 32000 may receive an address of data, which is to be read or written, from the card interface 31000 through the address bus ADDRESS, and may send it to the semiconductor memory system 34000. Further, the controller 32000 may receive or transfer data to be read or written through the data bus DATA connected with the card Interface 31000 or the semiconductor memory system 34000.

When the electronic device 30000 is connected with the host such as a PC, a tablet PC, a digital camera, a digital audio player, a mobile phone, console video game hardware, and a digital set-top box, the host may exchange data with the non-volatile memory 34000 through the card interface 31000 and the controller 32000.

While the invention has been described with respect to specific embodiments, it will be apparent to those skilled in the art that various changes and modifications may be made without departing from the spirit and scope of the invention as defined in the following claims.

What is claimed is:

1. An operation method of a flash memory system including a memory device, a controller and a host, the method comprising:
a first step of receiving data; and
a second step of obtaining a total number of error-corrected bits of the received data during a total decoding operation comprising one or more decoding operations.

2. The method of claim 1, wherein the second step comprises:
a third step of calculating error-corrected bits for each of the decoding operations; and
a fourth step of obtaining the total number of error-corrected bits of the received data by accumulating calculated error-corrected bits for each of the decoding operations.

3. The method of claim 1, wherein the second step comprises:
a fifth step of obtaining locations of the error bits of the received data;
a sixth step of error-correcting the error bits of the received data based on the locations of the error bits; and
a seventh step of obtaining the total number of error-corrected bits of the received data based on the error-corrected bits.

4. The method of claim 1, wherein each decoding operation of the total decoding operation comprises a predetermined decoding operation to the row constituent code and a predetermined decoding operation to the column constituent code.

5. The method of claim 4, further comprising:
an eighth step of determining whether the total decoding operation is successful.

6. The method of claim 5, further comprising:
when the total decoding operation fails as a determination result of the sixth step, a seventh step of obtaining total number of error-corrected bits of the received data by repeating the fifth and eighth steps a predetermined number of times.

7. The method of claim 5, further comprising:
when the total decoding operation is successful as a determination result of the sixth step, providing a host with the total number of error-corrected bits of the received data obtained up to the total decoding operation and a success flag.

8. The method of claim 6, further comprising:
before performing a seventh step of obtaining total number of error-corrected bits of the received data by repeating the third and sixth steps a predetermined number of times, determining whether the total decoding operation corresponds to a predetermined last total decoding operation.

9. The method of claim 8, further comprising:
when the total decoding operation does not correspond to the predetermined last total decoding operation, obtaining the total number of error-corrected bits of the received data by repeating the fifth and eighth steps a predetermined number of times.

10. The method of claim 8, further comprising:
when the total decoding operation corresponds to the predetermined last total decoding operation, providing a host with the total number of error-corrected bits of the received data obtained through a predetermined number of repetition of the total decoding operation and a fall flag.

11. A method for performing a predetermined total decoding operation to data comprising a plurality of row constituent codes and a plurality of column constituent codes, the method comprising:
a first step of performing a predetermined row constituent code decoding operation for the plurality of row constituent codes;
a second step of performing a predetermined column constituent code decoding operation for the plurality of column constituent codes;
a third step of determining whether the total decoding operation is successful;
a fourth step of determining whether the total decoding operation corresponds to a last total decoding operation of the predetermined total decoding operation when the total decoding operation fails; and
a fifth step of obtaining total number of error-corrected bits of the received data by repeating the first to fourth steps when the total decoding operation does not correspond to the last total decoding operation of the predetermined total decoding operation.

12. The method of claim 11, wherein the first step comprises:
a sixth step of obtaining locations of the error bits of the row constituent codes;
a seventh step of error-correcting the error bits of the row constituent codes based on the locations of the error bits of the row constituent codes; and
a eighth step of obtaining a number of error-corrected bits of the row constituent codes based on the error-corrected bits of the row constituent codes.

13. The method of claim 12, further comprising:
a ninth step of repeating the row constituent code decoding operation until a last row constituent code in the plurality of row constituent codes.

14. The method of claim 11, wherein the second step comprises:
a tenth step of obtaining locations of the error bits of the column constituent codes;
an eleventh step of error-correcting the error bits of the column constituent codes based on the locations of the error bits of the column constituent codes; and
a twelfth step of obtaining a number of error-corrected bits of the column constituent codes based on the error-corrected bits of the column constituent codes.

15. The method of claim 14, further comprising:
a thirteenth step of repeating the column constituent code decoding operation until a last column constituent code in the plurality of column constituent codes.

16. The method of claim 11, wherein the total number of error-corrected bits of the received data is determined based on the following:
ê=Σₗ₌₀{Σᵢe_{r,i}^{(l)}1_{r,i}^{(l)}+Σᵢe_{c,j}^{(l)}1_{c,j}^{(l)}},
where ê denotes the total number of error-corrected bits of the received data, e_{r,i}^{(l)} denotes a number of error-corrected bits of i-th row constituent code obtained through the row constituent code decoding operation to i-th row constituent code during l-th total decoding operation of the predetermined total decoding operation, e_{c,j}^{(l)} denotes a number of error-corrected bits of j-th column constituent code obtained through the column constituent code decoding operation to j-th column constituent code during l-th total decoding operation of the predetermined total decoding operation, 1_{r,i}^{(l)} denotes a case that the number (e_{r,i}^{(l)}) of error-corrected bits in the i-th row constituent code obtained through the row constituent code decoding operation to i-th row constituent code during l-th total decoding operation of the predetermined total decoding operation is greater than one, and 1_{c,j}^{(l)} denotes a case that the number (e_{c,j}^{(l)}) of error-corrected bits in the j-th column constituent code obtained through the column constituent code decoding operation to j-th column constituent code during l-th total decoding operation of the predetermined total decoding operation is greater than one.

17. The method of claim 11, wherein the total number of error-corrected bits of the received data is determined based on the following:
ê=Σₗ₌₀{(e_{r,i}^{(l)}−e_{r,i˜}^{(l)})1_{r,i}^{(l)}+Σᵢ(e_{c,j}^{(l)}−e_{c,j}^{˜(l)})1_{c,j}^{(l)}},
where ê denotes the total number of error-corrected bits of the received data, e_{r,i}^{(l)} denotes a number of error-corrected bits of l-th row constituent code obtained through the row constituent code decoding operation to i-th row constituent code during l-th total decoding operation of the predetermined total decoding operation, e_{c,j}^{(l)} denotes a number of error-corrected bits of j-th column constituent code obtained through the column constituent code decoding operation to j-th column constituent code during l-th total decoding operation of the predetermined total decoding operation, e_{r,i}^{˜(l)} denotes a backup number of error-corrected bits in the i-th row constituent code obtained through the row constituent code decoding operation to i-th row constituent code during l-th total decoding operation of the predetermined total decoding operation, e_{c,j}^{˜(l)} denotes a backup number of error-corrected bits in the j-th column constituent code obtained through the column constituent code decoding operation to j-th column constituent code during l-th total decoding operation of the predetermined total decoding operation, 1_{r,i}^{(l)} denotes a case that the number (e_{r,i}^{(l)}) of error-corrected bits in the i-th row constituent code obtained through the row constituent code decoding operation to i-th row constituent code during l-th total decoding operation of the predetermined total decoding operation is greater than one, and 1_{c,j}^{(l)} denotes a case that the number (e_{c,j}^{(l)}) of error-corrected bits in the j-th column constituent code obtained through the column constituent code decoding operation to j-th column constituent code during l-th total decoding operation of the predetermined total decoding operation is greater than one.

18. The method of claim 11, wherein the total number of error-corrected bits of the received data is determined based on the following:
ê=Σᵢ(e_{r,i}^{˜})+Σⱼ(e_{c,j}^{˜}),
where ê denotes the total number of error-corrected bits of the received data, e_{r,i}^{˜} denotes a backup number of error-corrected bits in the i-th row constituent code, which is a number of error-corrected bits in the i-th row constituent code obtained through successfully completed row constituent code decoding operation to i-th row constituent code or a last row constituent code decoding operation of the predetermined row constituent code decoding operation to the plurality of row constituent codes and is stored in a backup buffer of the l-th row constituent code, and e_{c,j}^{˜} denotes a backup number of error-corrected bits in the j-th column constituent code, which is a number of error-corrected bits in the j-th column constituent code obtained through successfully completed column constituent code decoding operation to j-th column constituent code or a last column constituent code decoding operation of the predetermined column constituent code decoding operation to the plurality of column constituent codes and is stored in a backup buffer of the j-th the column constituent code.

19. The method of claim 11, wherein the total number of error-corrected bits of the received data is determined based on the following:
ê=Σₗ₌₀{Σᵢ(e_{r,i}^{(l)}−2e_{r,i}^{˜(l)})1_{r,i}^{(l)}+Σᵢ(e_{c,j}^{(l)}−2e_{c,j}^{˜(l)})1_{c,j}^{(l)}},
where ê denotes the total number of error-corrected bits of the received data, e_{r,i}^{(l)} denotes a number of error-corrected bits of i-th row constituent code obtained through the row constituent code decoding operation to i-th row constituent code during l-th total decoding operation of the predetermined total decoding operation, e_{c,j}^{(l)} denotes a number of error-corrected bits of j-th column constituent code obtained through the column constituent code decoding operation to j-th column constituent code during l-th total decoding operation of the predetermined total decoding operation, e_{r,i}^{˜(l)} denotes a backup number of error-corrected bits in the i-th row constituent code obtained through the row constituent code decoding operation to i-th row constituent code during l-th total decoding operation of the predetermined total decoding operation, e_{c,j}^{˜(l)} denotes a backup number of error-corrected bits in the j-th column constituent code obtained through the column constituent code decoding operation to j-th column constituent code during l-th total decoding operation of the predetermined total decoding operation, 1_{r,i}^{(l)} denotes a case that the number (e_{r,i}^{(l)}) of error-corrected bits in the i-th row constituent code obtained through the row constituent code decoding operation to i-th row constituent code during l-th total decoding operation of the predetermined total decoding operation is greater than one, and 1_{c,j}^{(l)} denotes a case that the number (e_{c,j}^{(l)}) of error-corrected bits in the j-th column constituent code obtained through the column constituent code decoding operation to j-th column constituent code during l-th total decoding operation of the predetermined total decoding operation is greater than one.

20. The method of claim 11, further comprising:
when the total decoding operation is successful as a determination result of the third step, providing a host with the total number of error-corrected bits of the received data obtained up to the successful total decoding operation and a success flag without performing remaining total decoding operation among the predetermined total decoding operations.

21. The method of claim 11, further comprising:
when the total decoding operation corresponds to the last total decoding operation of the predetermined total decoding operation as a determination result of the fourth step, providing a host with the total number of error-corrected bits of the received data obtained through the predetermined total decoding operation and a fail flag.
